(19) United States
(12) Patent Application Publication
(10) Pub. No.: US 2023/0231118 A1
(43) Pub. Date: Jul. 20, 2023

(54) COMPOSITE NANOARCHITECTURE UNIT, MULTILAYER COMPOSITE, AND METHOD FOR MANUFACTURING COMPOSITE NANOARCHITECTURE UNIT

(71) Applicant: OKINAWA INSTITUTE OF SCIENCE AND TECHNOLOGY SCHOOL CORPORATION, Okinawa (JP)

(72) Inventors: Panagiotis GRAMMATIKOPOULOS, Okinawa (JP); Marta HARO, Okinawa (JP); Junlei ZHAO, Shenzhen (CN); Emilio Jose JUAREZ-PEREZ, Okinawa (JP)

(21) Appl. No.: 18/011,357

(22) PCT Filed: Sep. 7, 2021
(86) PCT No.: PCT/JP2021/032778

§ 371 Date: Dec. 19, 2022

Related U.S. Application Data
(60) Provisional application No. 63/075,455, filed on Sep. 8, 2020.

(51) Int. Cl. H01M 4/38; H01M 4/134; H01M 4/04; H01M 4/1395

(52) U.S. Cl. CPC H01M 4/386; H01M 4/134; H01M 4/0471; H01M 4/1395; H01M 4/0423; H01M 2004/027

(57) ABSTRACT

A composite nanoarchitecture unit is disclosed. The unit comprises a columnar film grown on top of another layer where the columns touch each other at the top forming arches having optimized characteristics. This nanoarchitecture unit, called nano-vault, achieves high mechanical stability for films under strong and variable stress action.

### TECHNICAL FIELD

This invention is concerning Si anodes for LIBs and other materials and applications where surface mechanics play a critical role.

### BACKGROUND ART

Alloying anode materials are a promising alternative to graphite for high-energy LIBs because of their up-to-tenfold increase in theoretical capacity. However, the huge volume change during lithiation hinders formation of stable solid electrolyte interfaces (SEIs), and causes electrode fracture. Low mechanical stability of LIBs with Si anodes is an impediment to their commercialisation, but composite anodes containing Si additives are already being marketed. However, the mechanical stability of Si is the main parameter that limits both particle size and fraction of Si in composite anodes. Thus, increasing the amount of Si in anodes while maintaining satisfactory mechanical stability remains a challenge for high-energy LIB technology.

### SUMMARY OF INVENTION

### Technical Problem

The main mechanical issue is that a compressive stress builds up during lithiation, which is subsequently released during delithiation. When this compressive stress exceeds the yield strength, the electrode deforms to accommodate the volume change. Therefore, tuning the elastic modulus, E, of Si anodes is of utmost importance. E quantifies the strain (deformation defined as displacement divided by a reference length, ε) in a material when a stress (force per area, σ) is applied (E=σ/ε).

Hence, Si electrodes with low E values allow the material to deform easily, maximizing the capacity of the anode at the cost of decreased mechanical stability. This problem can be addressed using shells to seal nanostructured Si while maintaining the integrity of the electrode and allowing the formation of a stable SEI; however, this leads to a reduction in LIB energy density. Another strategy to enhance the mechanical stability of Si-based anodes is by increasing the anode's elastic modulus either with new binders for Si composites or by physically constraining volume expansion. Again, these approaches restrict the LIB energy density.

### Solution to Problem

The present invention has been made in view of the above-described circumstances. To solve the aforementioned problem, a first aspect of the present invention is intended for a composite nanoarchitecture unit, comprising a columnar film grown on top of another layer where the columns touch each other at the top forming arches having optimized characteristics.

The second aspect of the present invention is intended for the composite nanoarchitecture unit of the first aspect, wherein the columnar film is an amorphous Si film in an annealed state.

The third aspect of the present invention is intended for the composite nanoarchitecture unit of the first aspect, wherein the columnar film is grown on top of a layer of metallic nanoparticles.

The fourth aspect of the present invention is intended for the composite nanoarchitecture unit of the first aspect, wherein the optimized characteristics include at least one of a low lithium consumption during formation of solid electrolyte interface in Li-Ion Batteries, high Coulombic efficiency, and high mechanical stability pertinent to any application where the surface of the film is under strong and variable stress action.

The fifth aspect of the present invention is intended for a multilayer composite including at least two vertical repetitions of the composite nanoarchitecture unit of the first aspect.

The sixth aspect of the present invention is intended for the multilayer composite of the fifth aspect, wherein the optimized characteristics compared with those of the monolayered structure include both a high Coulombic efficiency of a lithium ion battery and the mechanical stability of the film, indicating arch action reinforcement.

The seventh aspect of the present invention is intended for a manufacturing method for a composite nanoarchitecture unit. The method comprises the steps of: a) depositing nanoparticles on substrates from the gas phase; and b) growing a columnar film on a layer of nanoparticles. Column diameters in the columnar film increased with thickness until the column tops contacted one another, closing the surface via the formation of an arched structure in the step b).

The eighth aspect of the present invention is intended for the manufacturing method of the seventh aspect, wherein growth of the columnar film is stopped as soon as possible after arch formation in the step b).

The ninth aspect of the present invention is intended for the manufacturing method of the seventh aspect, further comprising the step of c) thermal annealing of the columnar film.

The tenth aspect of the present invention is intended for the manufacturing method of the seventh aspect, wherein the columnar film is an amorphous Si film.

The eleventh aspect of the present invention is intended for the manufacturing method of the seventh aspect, wherein the nanoparticles are metallic nanoparticles.

### Advantageous Effects of Invention

This work addresses this challenge utilising a specific columnar thin film structure denoted as vaulted structure, a novel nanoarchitecture synthesised using nanoparticles. The name alludes to the civil engineering definition of a multi-arch structure sustained on columns, characterised by its high elastic modulus. According to the first to the eleventh aspect of the present invention, the nano-vault structural unit is grown using nanoparticles as scaffold, enabling vertical repetition of the composite in a multilayer that reinforces the optimized characteristics observed in the monolayer. As a result, Si anodes with vaulted structures simultaneously show high mechanical stability and low lithium consumption during formation of SEI, addressing the two main challenges for Si anode commercialisation. This optimal electrochemical performance is associated with a distinct transition in mechanical behaviour exactly when individual Si columns merge to form closed arches (but not beyond that point, with further growth of amorphous Si film on top). The introduction of vaulted structure and arch action brings many new possibilities in the design of new materials for batteries, but also for other applications in which the surface is under strong and variable stress action.
New strategy:
   No binder
   No solvents
   Flexibility in the design
   High control
Nano-structure unit:
   Nanostructure of well-known civil engineering architecture
   Reproducible in Z-axis
   Improved properties
Optimized properties:
   Inner voids
   Sealed surface
   High mechanical stability
Application in Li-Ion Batteries:
   High capacity
   Fast charge/discharge rate
   High Coulombic efficiency

### BRIEF DESCRIPTION OF DRAWINGS

FIG. 1A is schematic diagram of the columnar growth process of Si amorphous thin film;

FIG. 1B is schematic diagram of the columnar growth process of Si amorphous thin film;

FIG. 1C is schematic diagram of the columnar growth process of Si amorphous thin film;

FIG. 1D is schematic diagram showing the mechanical response of a columnar structure of Si amorphous film to nanoindenter force;

FIG. 1E is schematic diagram showing the mechanical response of a vaulted structure of Si amorphous film to nanoindenter force;

FIG. 1F is schematic diagram showing the mechanical response of a sedimentary structure of Si amorphous film to nanoindenter force;

FIG. 2A is a TEM lamella image of sample 54^{V};

FIG. 2B is a TEM lamella image of sample 216^{S};

FIG. 2C is a SEM top-view image of sample 54^{V};

FIG. 2D is a SEM top-view image of sample 216^{S};

FIG. 2E is a SEM cross-section image of sample 54^{V};

FIG. 2F is a SEM cross-section image of sample 216^{S};

FIG. 3A shows topography and elastic moduli of sample 25^{C};

FIG. 3B shows topography and elastic moduli of sample 54^{V};

FIG. 3C shows topography and elastic moduli of sample 155^{S};

FIG. 3D shows histograms of E for several indicated samples;

FIG. 3E shows E values with the highest weights in the histogram plotted against film thickness, h, of all samples;

FIG. 4A shows a slice of a growth simulation of Si deposited on a nanoparticle viewed along the (110) direction;

FIG. 4B shows a slice of a growth simulation of Si deposited without the nanoparticle viewed along the (110) direction;

FIG. 4C shows eight instances of the growth simulation with nanoparticles, sliced and viewed along the (100) direction;

FIG. 4D shows evolution of the force-depth curve of the eight instances; a compress-hold-decompress loop was performed with a flat diamond carbon tip at 500 K;

FIG. 4E shows initial linear elastic deformation of the eight instances within displacements of 2 nm, with linear regression fitting (solid lines);

FIG. 4F shows stiffness of the corresponding structures as a function of thickness;

FIG. 5A shows charge capacity (Si electrode delithiation) of Si films grown on TaNS and Cu foil substrates;

FIG. 5B shows Coulombic efficiency of semibatteries cycled at 0.5 C between 0.01 and 1V of Si films grown on TaNS and Cu foil substrates;

FIG. 5C shows charge capacity (Si electrode delithiation) of Si films grown on TaNS and Li foil substrates;

FIG. 5D shows Coulombic efficiency of semibatteries cycled at 0.5 C between 0.01 and 1V of Si films grown on TaNS and Li foil substrates;

FIG. 6 is schematic representation of the experimental setup;

FIG. 7A shows thickness of Si films deposited on TaNS as a function of sputtering times;

FIG. 7B shows thickness of Si films deposited on TaNS with different thicknesses;

FIG. 8A shows X-ray reflectivity (XRR) measurements of a plain Cu wafer surface including a native copper oxide layer;

FIG. 8B shows X-ray reflectivity (XRR) measurements of Si film growth without pre-deposited Ta nanoparticles;

FIG. 8C shows X-ray reflectivity (XRR) measurements of Si film growth on substrates with Ta nanoparticles (25^{C});

FIG. 8D shows X-ray reflectivity (XRR) measurements of Si film growth on substrates with Ta nanoparticles (54^{V});

FIG. 8E shows X-ray reflectivity (XRR) measurements of Si film growth on substrates with Ta nanoparticles (110^{S});

FIG. 8F shows X-ray reflectivity (XRR) measurements of Si film growth on substrates with Ta nanoparticles (216^{S});

FIG. 9A shows Si and Ta at. % concentrations vs etching times for AR ion etching of a sample with Si and Ta co-deposited in a matrix configuration using X-ray photoelectron spectroscopy (XPS);

FIG. 9B shows 2p peak for Si for AR ion etching of a sample with Si and Ta co-deposited in a matrix configuration using X-ray photoelectron spectroscopy (XPS);

FIG. 9C shows 4f peak for Ta for Ar ion etching of a sample with Si and Ta co-deposited in a matrix configuration using X-ray photoelectron spectroscopy (XPS);

FIG. 10 is a scanning electron microscopy (SEM) cross-section image of sample 25^{C} grown on a Si substrate;

FIG. 11A shows elastic modulus histogram of Si sputtered for 60 minutes on the TaNS (sample 110^{S}), for two different substrates (Cu, Si);

FIG. 11B shows elastic modulus histogram of Si sputtered for 60 minutes directly on the substrate without nanoparticles, for two different substrates (Cu, Si);

FIG. 12A shows Functions of elastic modulus and height for the samples 15^{C} and 25^{C};

FIG. 12B shows Functions of elastic modulus and height for the samples 35^{C} and 54^{V};

FIG. 12C shows Functions of elastic modulus and height for the samples 110^{S} and 155^{S};

FIG. 12D shows Functions of elastic modulus and height for the sample 201^{S};

FIG. 13A shows topography for exemplary sample of vaulted structure (54^{V}) measured using PF-QNM;

FIG. 13B shows elastic moduli for exemplary sample of vaulted structure (54^{V}) measured using PF-QNM;

FIG. 13C shows histograms of E for exemplary sample of vaulted structure (54^{V}) measured using PF-QNM;

FIG. 13D shows topography for exemplary sample of sedimentary structure (155^{S}) measured using PF-QNM;

FIG. 13E shows elastic moduli for exemplary sample of sedimentary structure (155^{S}) measured using PF-QNM;

FIG. 13F shows histograms of E for exemplary sample of sedimentary structure (155^{S}) measured using PF-QNM;

FIG. 14A shows Si deposition on a single nanoparticle by MD simulations sliced and viewed along the (100) direction;

FIG. 14B shows Si deposition on a single nanoparticle by MD simulations sliced and viewed along the (110) direction;

FIG. 14C shows the surface mesh inside the deposited layer (i.e., without the atoms) in 3D;

FIG. 15 shows Si deposited on two neighbouring nanoparticles;

FIG. 16A shows elastic deformation of the corresponding structures, as shown in FIG. 4C, during the unloading process;

FIG. 16B shows the decompression stiffness of the corresponding structures as a function of structure thickness;

FIG. 17A shows charge capacity (Si electrode delithiation) of Si samples;

FIG. 17B shows Coulombic efficiency of Si samples;

FIG. 18A is a low magnification SEM image of sample 15^{C} after 3 charge-discharge cycles and scratching with a diamond pen ;

FIG. 18B is a low magnification SEM image of sample 54^{V} after 3 charge-discharge cycles and scratching with a diamond pen;

FIG. 18C is a low magnification SEM image of sample 155^{S} after 3 charge-discharge cycles;

FIG. 18D is a cross-section SEM image of sample 15^{C} after 3 charge-discharge cycles and scratching with a diamond to reveal the film edge;

FIG. 18E is a cross-section SEM image of sample 54^{V} after 3 charge-discharge cycles and scratching with a diamond to reveal the film edge;

FIG. 18F is a cross-section SEM image of sample 155^{S} after 3 charge-discharge cycles;

FIG. 18G is a high magnification SEM image of the cycled anodes of sample 15^{C} after 3 charge-discharge cycles;

FIG. 18H is a high magnification SEM image of the cycled anodes of sample 54^{V} after 3 charge-discharge cycles;

FIG. 18I is a high magnification SEM image of the cycled anodes of sample 155^{S} after 3 charge-discharge cycles;

FIG. 19 shows volume expansion of the electrode 54^{V} in a lithium semibattery at 0.5 C.

FIG. 20A shows Nyquist plots of 54^{V} and 15^{C} registered at an open circuit after 3 cycles.

FIG. 20B shows Nyquist plots of 54^{V} and 15^{C} registered at an open circuit after 10 cycles.

FIG. 20C shows Nyquist plots of 54^{V} and 15^{C} registered at an open circuit after 50 cycles.

FIG. 20D shows Nyquist plots of 54^{V} and 15^{C} registered at an open circuit after 75 cycles.

FIG. 21A shows Charge capacity (Si electrode delithiation) of Si samples;

FIG. 21B shows Coulombic efficiency of Si samples;

FIG. 22A is TEM lamella image of D54^{V} sample grown on Si substrate before lithiation-delithiation cycling;

FIG. 22B is SEM image of D54^{V} sample grown on Si substrate before lithiation-delithiation cycling;

FIG. 23A shows elastic modulus measured using PF-QNM of the D54^{V} sample;

FIG. 23B is a histogram of elastic modulus of the D54^{V} and 54^{V} samples;

FIG. 24A shows charge (delithiation) capacity of LIB semibatteries cycled at 0.5 C for D54^{V} and 54^{V} samples;

FIG. 24B shows Coulombic efficiency of LIB semibatteries cycled at 0.5 C for D54^{V} and 54^{V} samples;

FIG. 25 is a SEM image of sample D54^{V} after three lithiation-delithiation cycles;

### DESCRIPTION OF EMBODIMENTS

### <1. Summary of the Invention>

Nanomaterials undergoing cyclic swelling-deswelling benefit from inner void spaces that help accommodate significant volumetric changes. Such flexibility, however, typically comes at a price of reduced mechanical stability, which leads to component deterioration and, eventually, failure. Here, we identify the optimal building block for Si-based Li-ion battery (LIB) anodes, fabricate it with a ligand- and effluent-free cluster beam deposition method, and prove its robustness by atomistic computer simulations. A columnar amorphous-Si film was grown on a Ta-nanoparticle scaffold due to its shadowing effect. PeakForce quantitative nanomechanical mapping revealed a critical point of change in mechanical behaviour when columns touched forming a vaulted structure. The resulting maximisation of mechanical strength lies on arch action, a well-known civil engineering concept. The vaulted nanostructure unit sealed the electrode surface and reduced the electrode/electrolyte interface while dissipating lithiation stress. Its vertical repetition in a double-layered aqueduct-like structure improved both the capacity stability and Coulombic efficiency of the LIB. These results highlight the exploitation of arch action at the nanoscale, successfully harnessing macroscale strategies toward mechanically stable nanostructures.

### <2. Detailed Description of the Drawing>

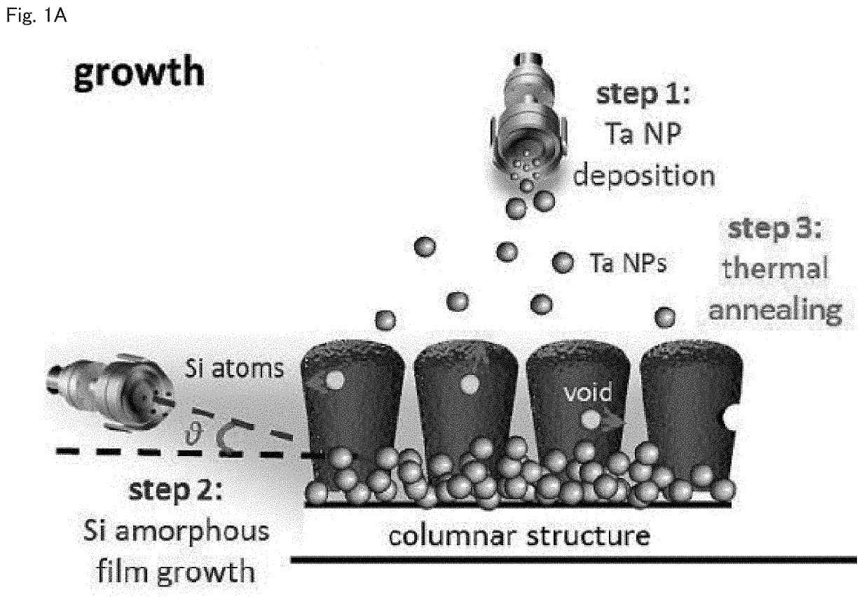

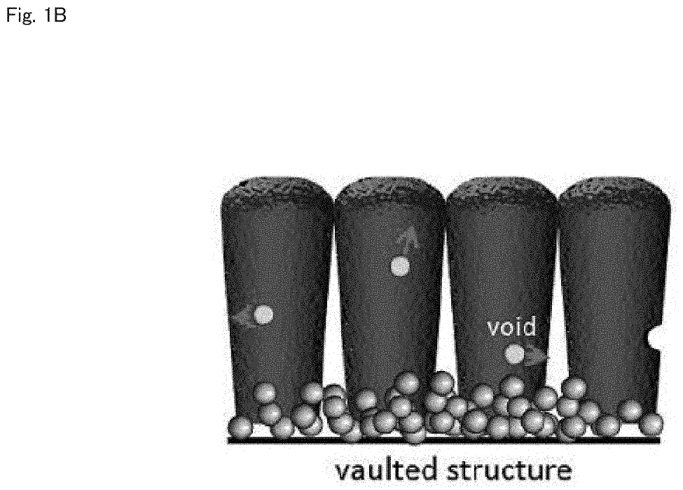

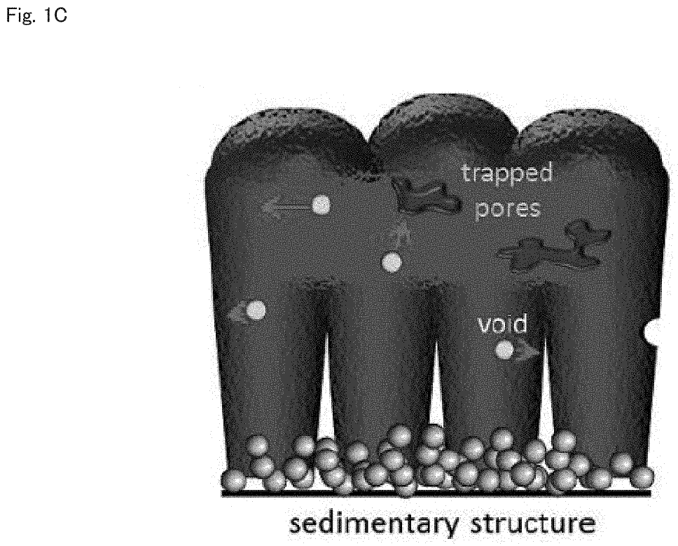

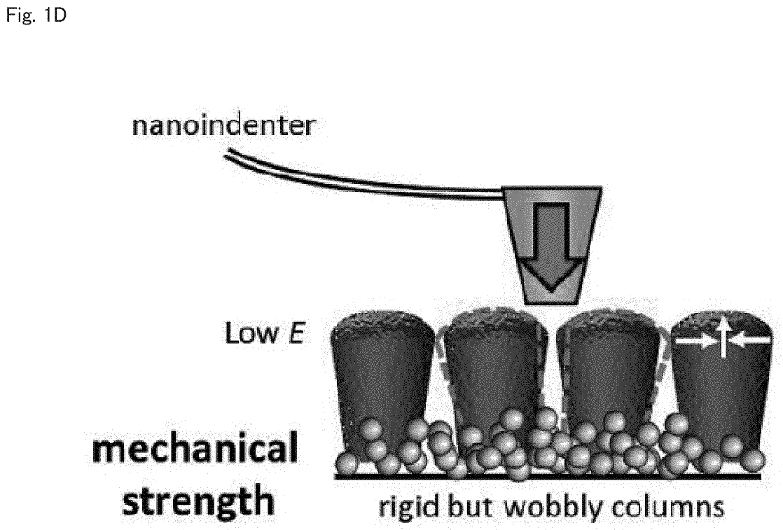

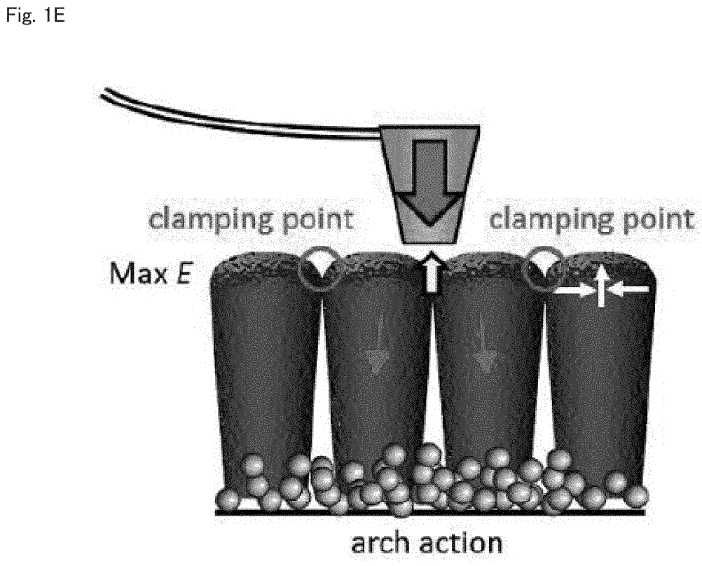

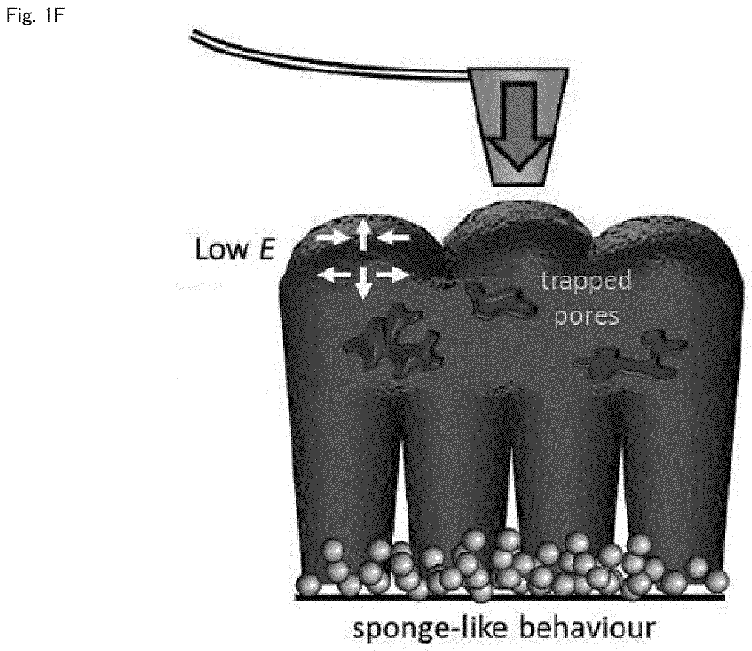

FIG. 1A-1F show design strategy of TaNS-Si amorphous film composite anodes and their structural and mechanical relationships. FIG. 1A-1C show schematic breakdown of growth process into three steps: deposition of TaNS, columnar growth of Si amorphous film exploiting the shadowing effect of the TaNS, and thermal annealing at 150° C. enhancing the mobility and consequent annihilation of voids at open surfaces. The mechanical response under the force of the nanoindenter is indicated for the three structures under study: FIG. 1D, columnar, FIG. 1E, vaulted, and FIG. 1F, sedimentary. The nanoindenter for PF-QNM measurements is shown above the structure, exerting a compressive force on Si samples. White arrows indicate film stresses, irrespective of indentation; the film response under the nanoindenter is shown in yellow. Dashed lines indicate sample deformations and small arrows represent the force distribution in the columns.

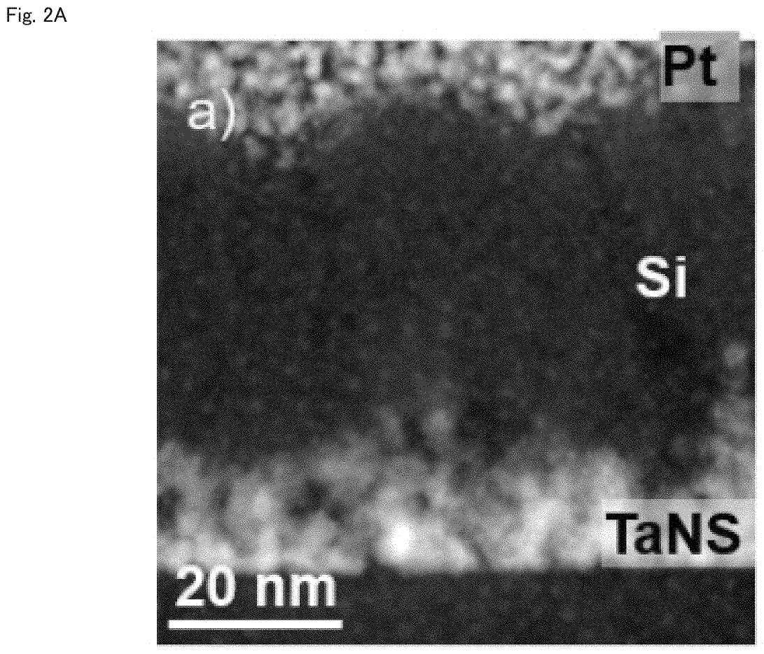

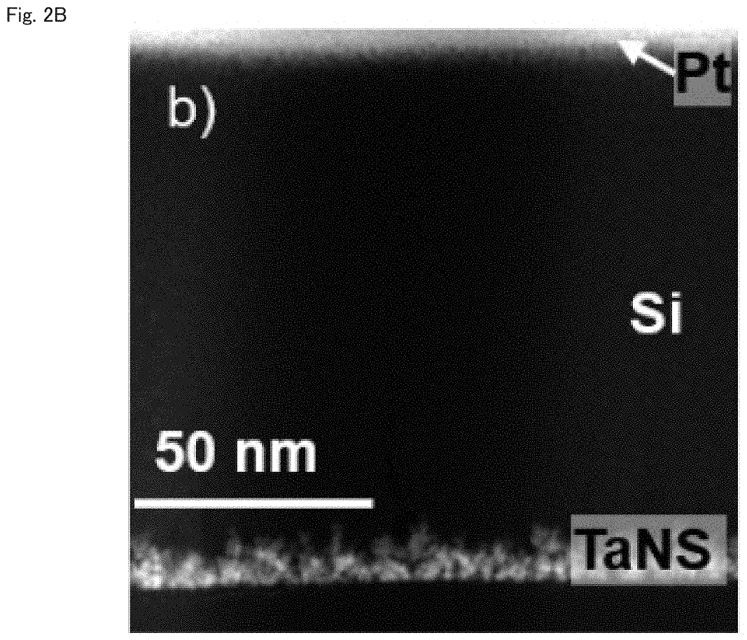

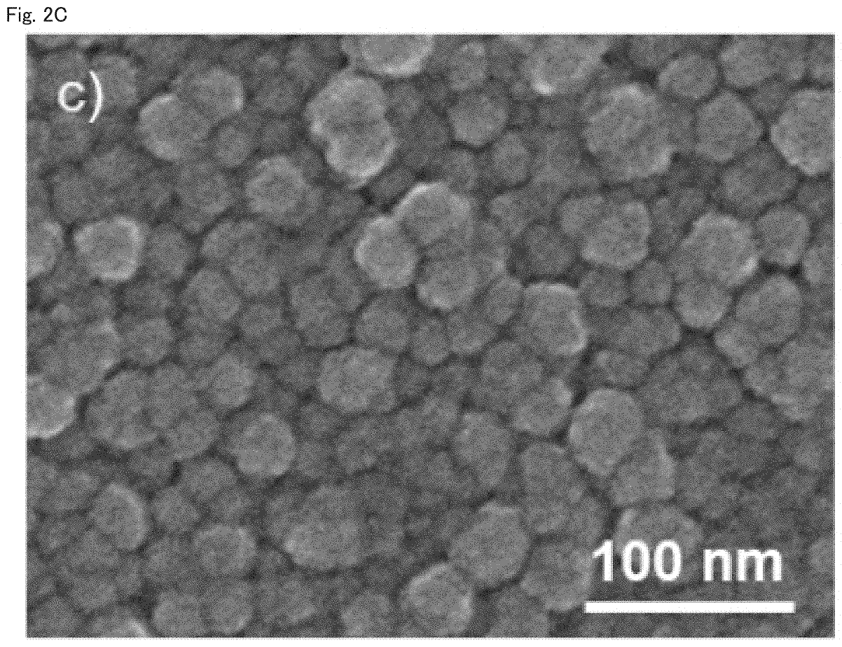

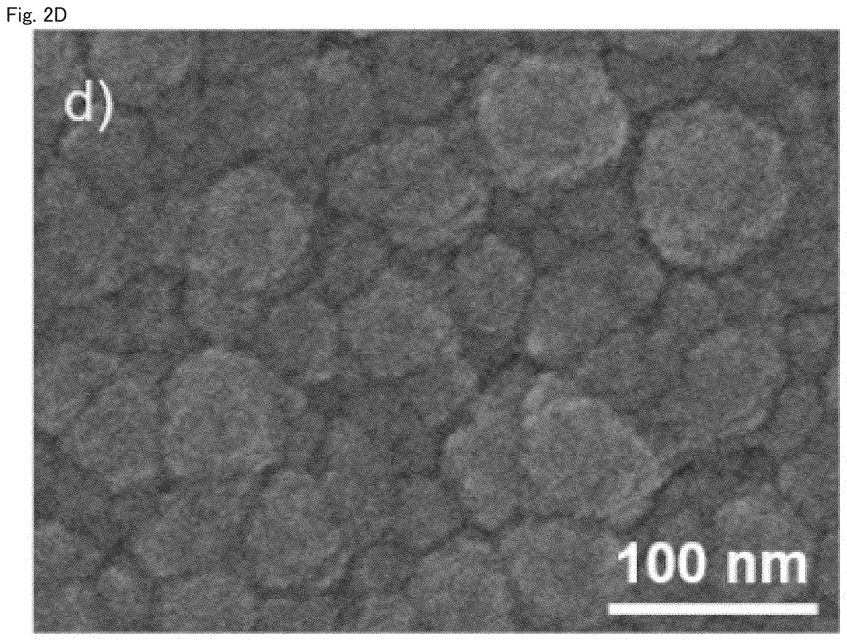

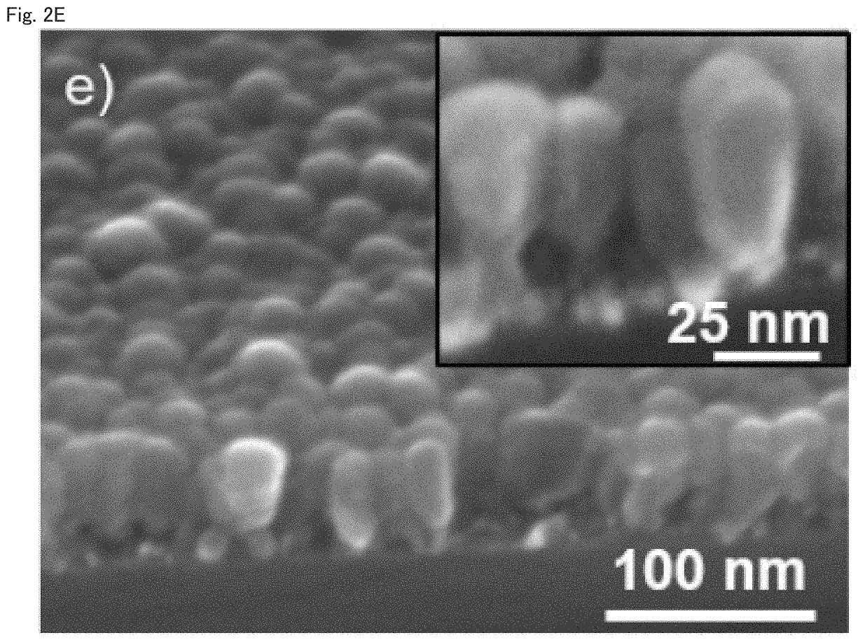

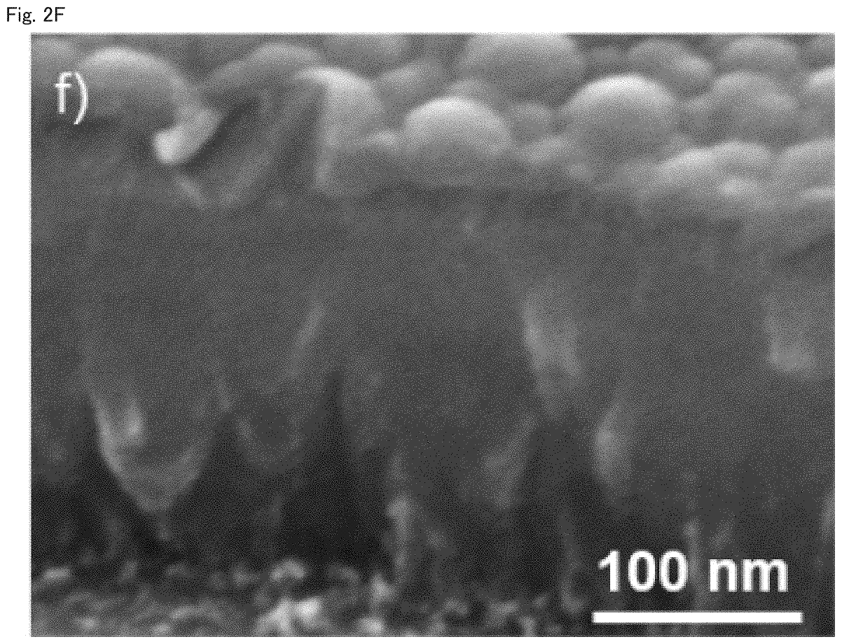

FIG. 2A-2F shows structural characterisation of Si thin films grown on TaNS. TEM lamella images of samples: FIG. 2A, 54^{V} and FIG. 2B, 216^{S} show the nanoparticulate nature of TaNS and the amorphous nature of Si. The observed Pt layer was deposited during lamella fabrication. SEM top-view images of samples: FIG. 2C, 54^{V} and FIG. 2D, 216^{S}, and corresponding cross-section images: FIG. 2E, 54^{V} (inset is magnified) and FIG. 2F, 216^{S}. 54^{V} corresponds to the vaulted structure, where column tops contact one another, while in 216^{S} structure columns already merge into a continuous film with Volmer-Weber growth, as the domed morphology suggests (sedimentary structure). The substrate used for preparation of samples for this structural characterisation is Si (111).

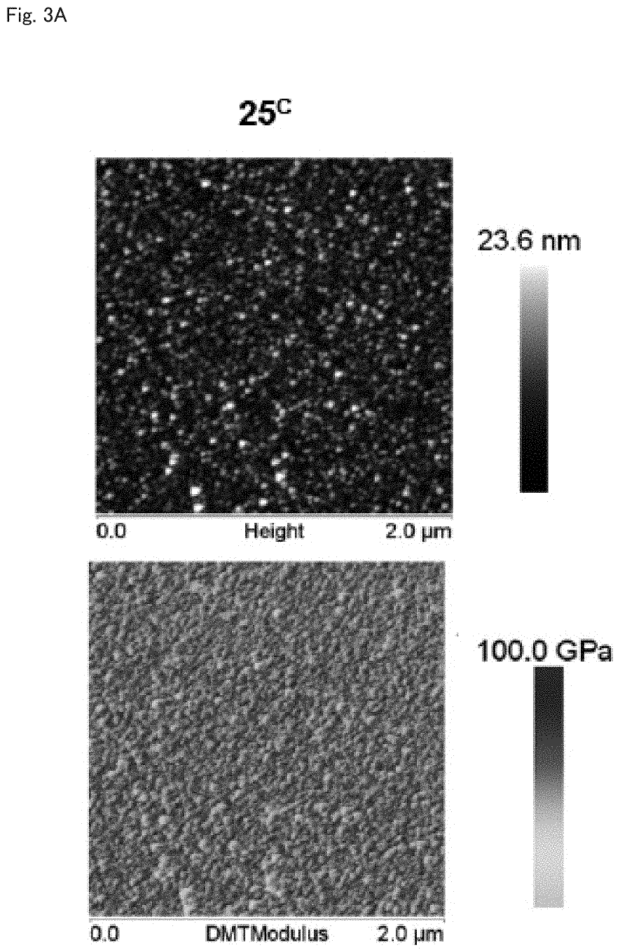

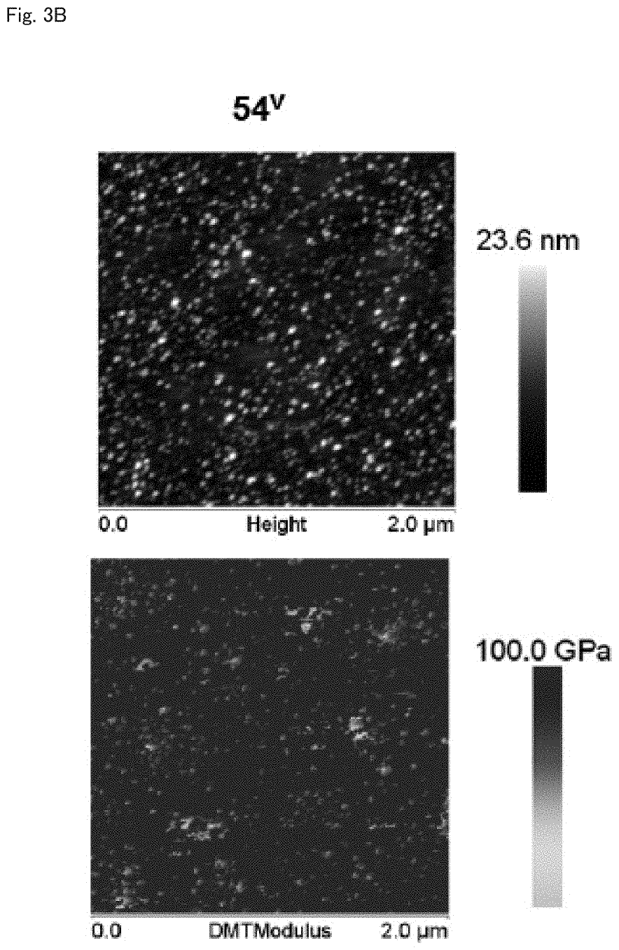

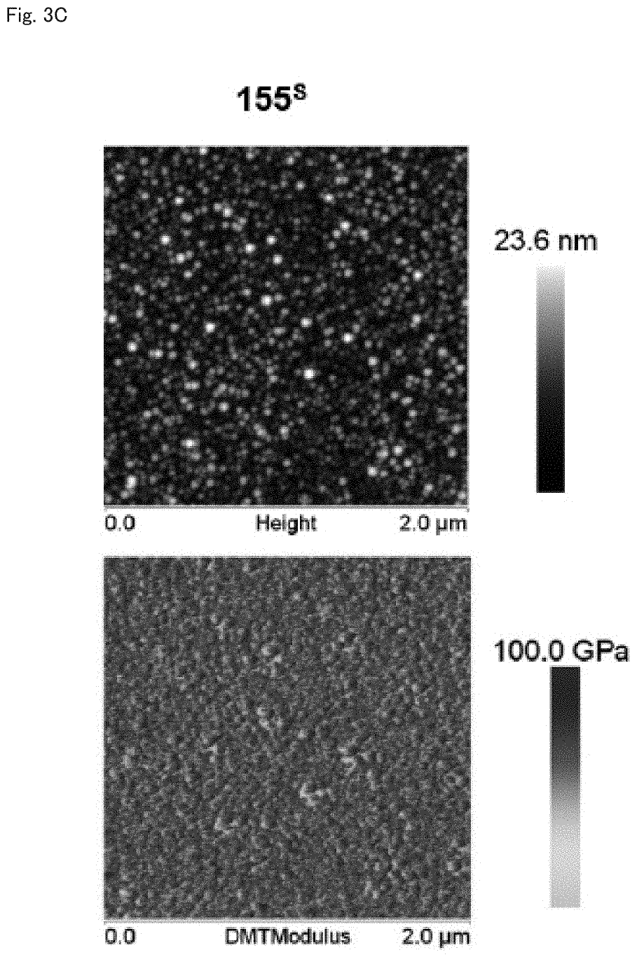

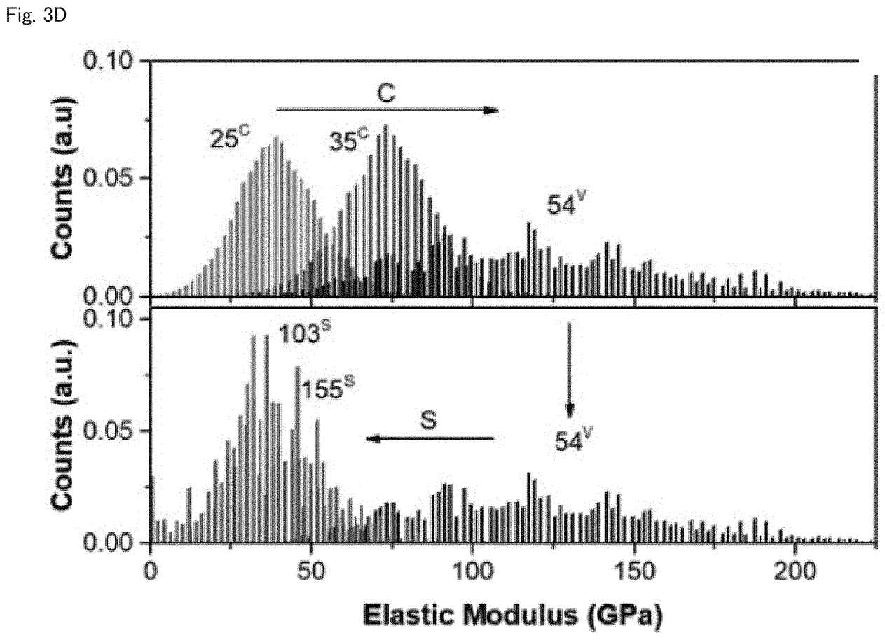

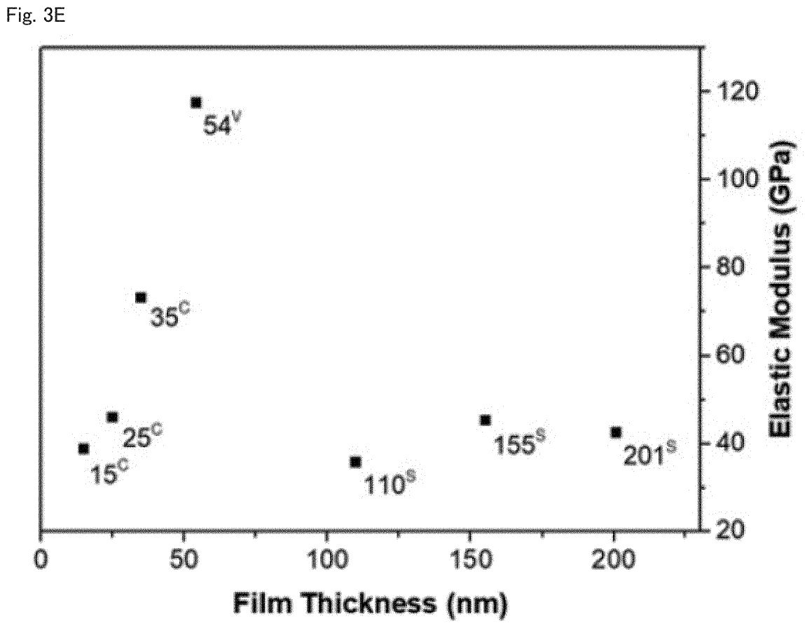

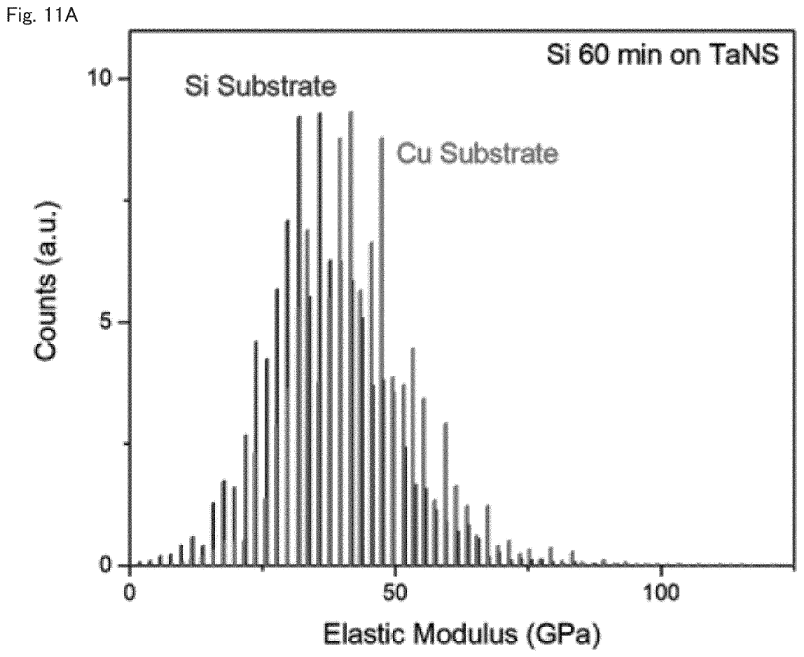

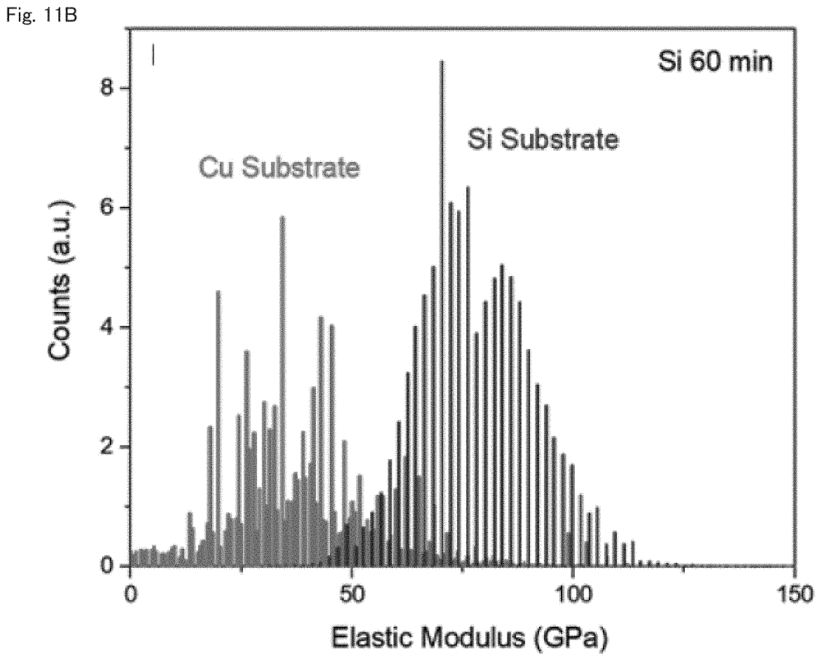

FIG. 3A-3E show mechanical properties measured using PF-QNM of Si films of different thicknesses grown on TaNS. The substrate used for preparation of samples is Si (111), but similar results are obtained for Cu foil substrates (FIG. 11). FIG. 3A shows topography and elastic moduli of sample 25^{C}. FIG. 3B shows topography and elastic moduli of sample 54^{V}. FIG. 3C shows topography and elastic moduli of sample 155^{S}. The same scale is used in E mappings of the three samples for easier comparison; note that E of 54^{V} is saturated in a high fraction of the mapping. FIG. 3D shows histograms of E for several indicated samples. E increases from the columnar to the vaulted structure (upper histogram) and decreases for the sedimentary structure (lower histogram). FIG. 3E shows E values with the highest weights in the histogram plotted against film thickness, h, of all samples. The change of E vs. h corresponds to the transition from columnar to Volmer-Weber Si growth, which is the region where columns top touch and form a vaulted structure.

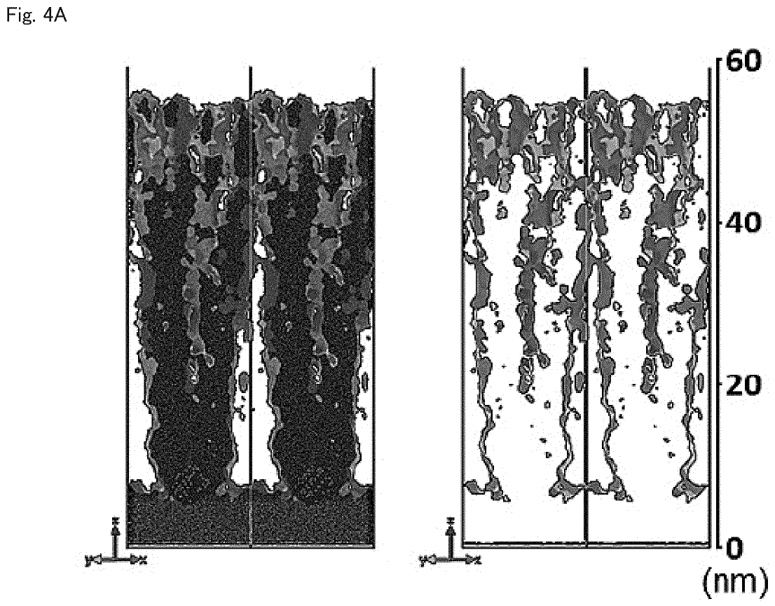

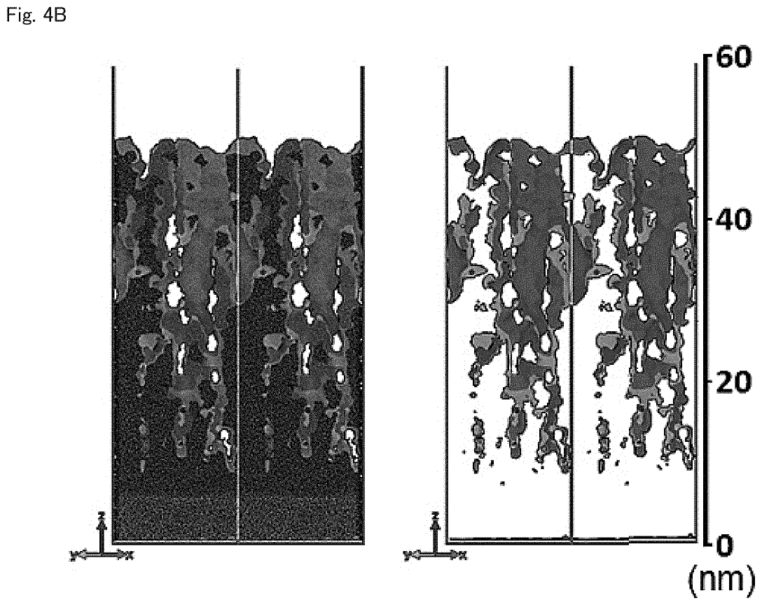

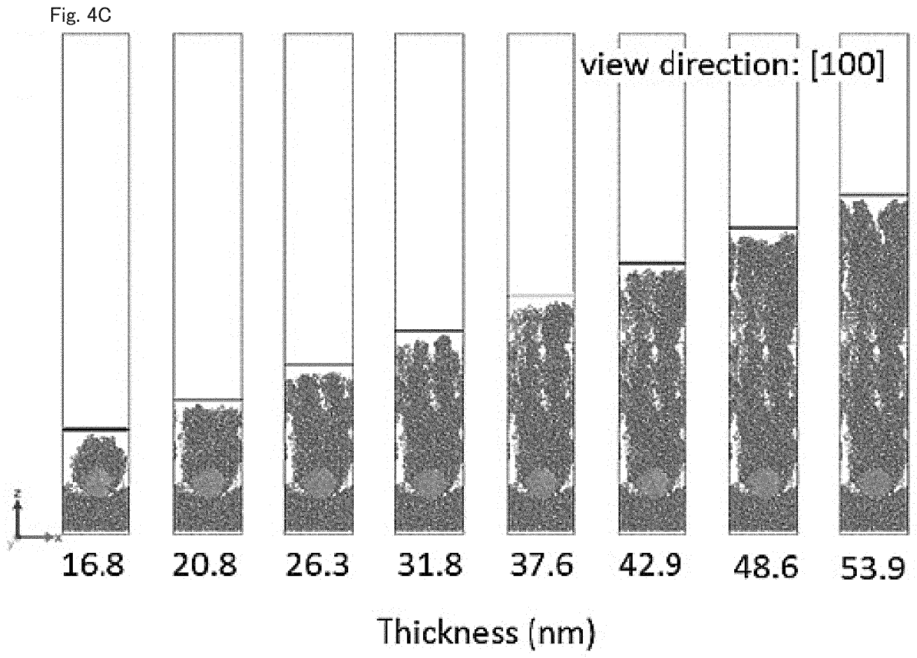

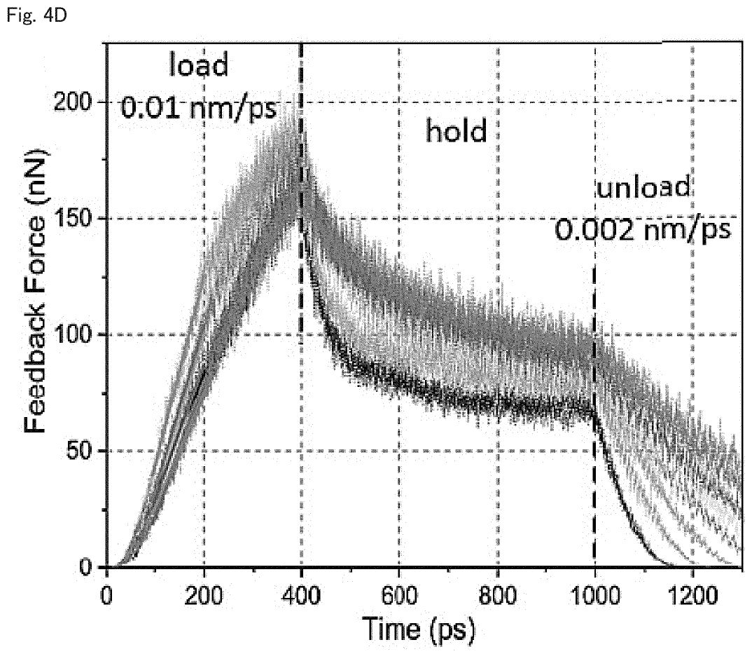

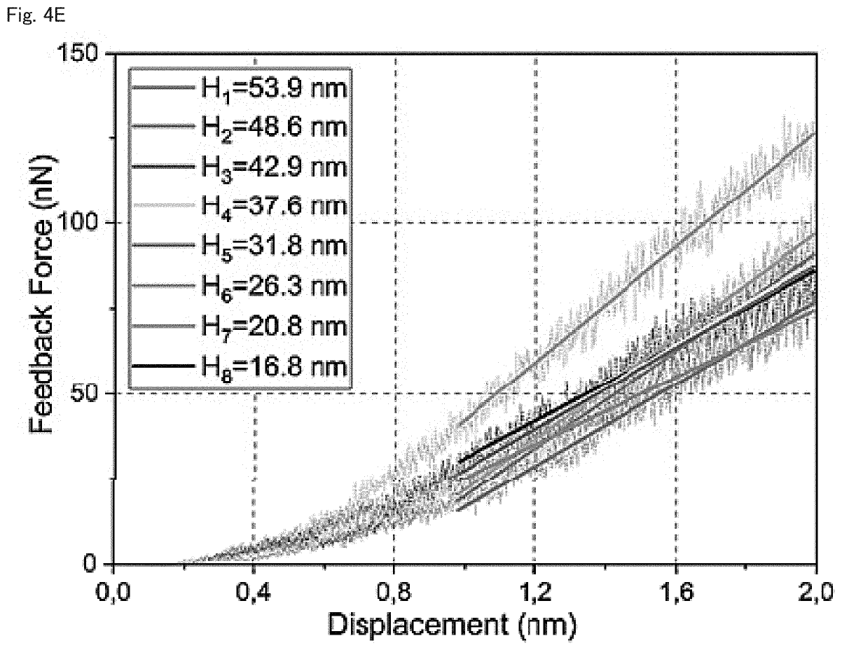

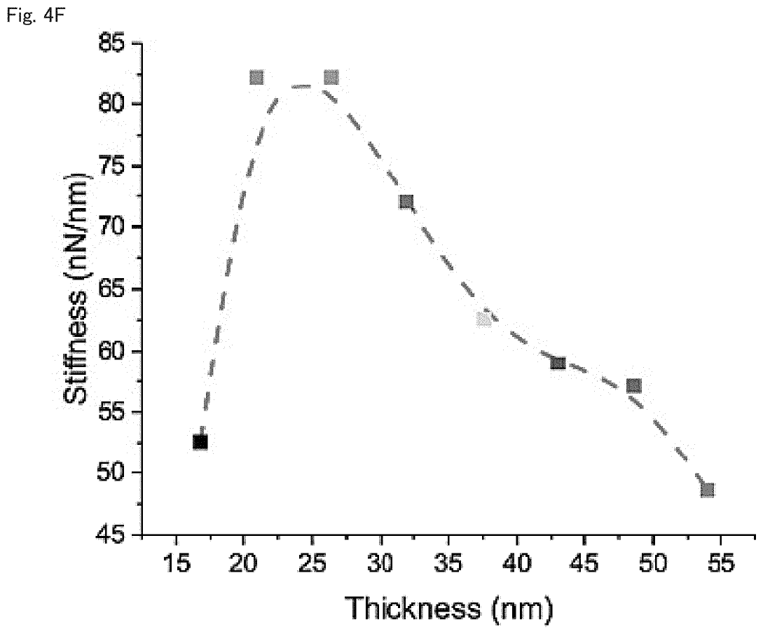

FIG. 4A-4F show correlation between morphology and mechanical properties by MD simulations. FIG. 4A shows that Si deposited on a Ta nanoparticle (duplicated along the (100) direction, due to periodic boundary conditions) at 500 K follows columnar growth and forms a vaulted structure. The simulation box, sliced for clear observation, is viewed along the (110) direction. The right panel only depicts the sliced surface mesh inside the deposited layer (i.e., without the atoms), indicating the presence of voids. FIG. 4B shows same but without the TaNS. A sedimentary structure forms from the start of the deposition, also leading to extensive voids throughout. FIG. 4C shows eight instances with TaNS selected from the growth simulations, sliced and viewed along the (100) direction. FIG. 4D shows evolution of the force-depth curve; a compress-hold-decompress loop was performed with a flat diamond carbon tip at 500 K. FIG. 4E shows initial linear elastic deformation within displacements of 2 nm, with linear regression fitting (solid lines). FIG. 4F shows stiffness of the corresponding structures as a function of thickness, clearly demonstrating the rigidity of the vaulted structure, in remarkable agreement with the experimental PF-QNM measurements of FIG. 3C.

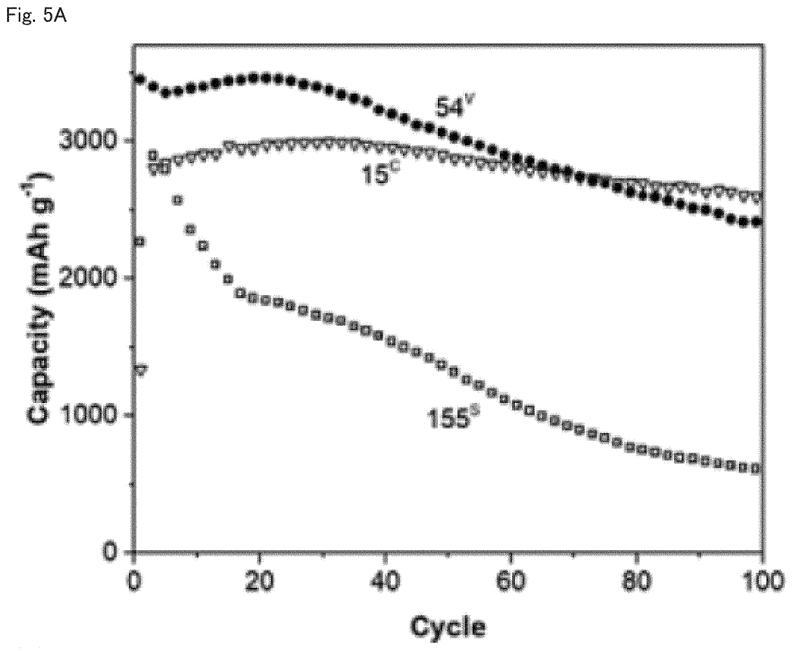

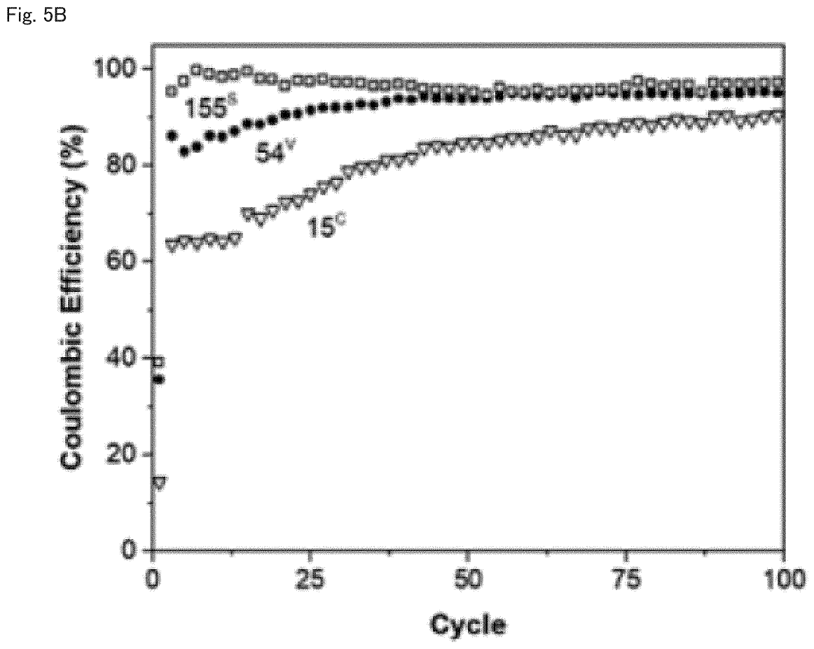

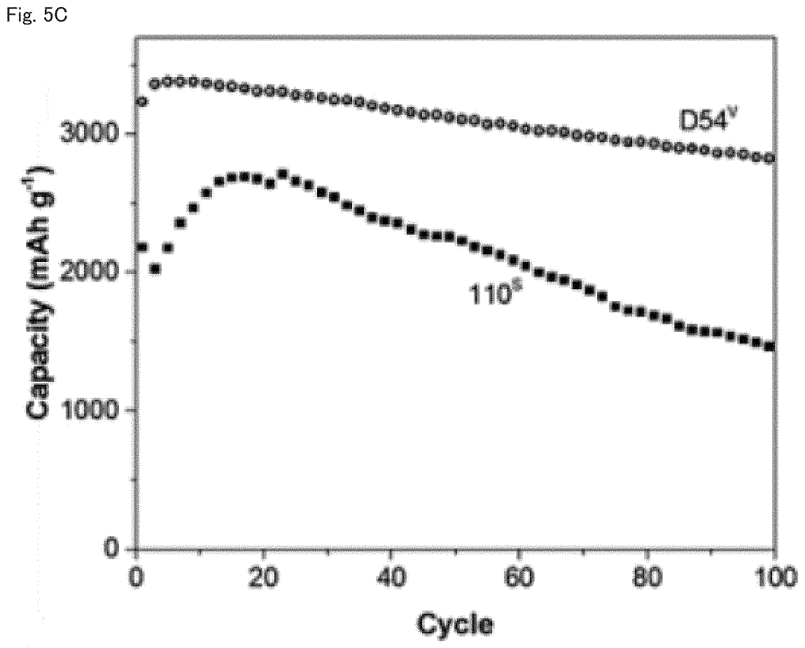

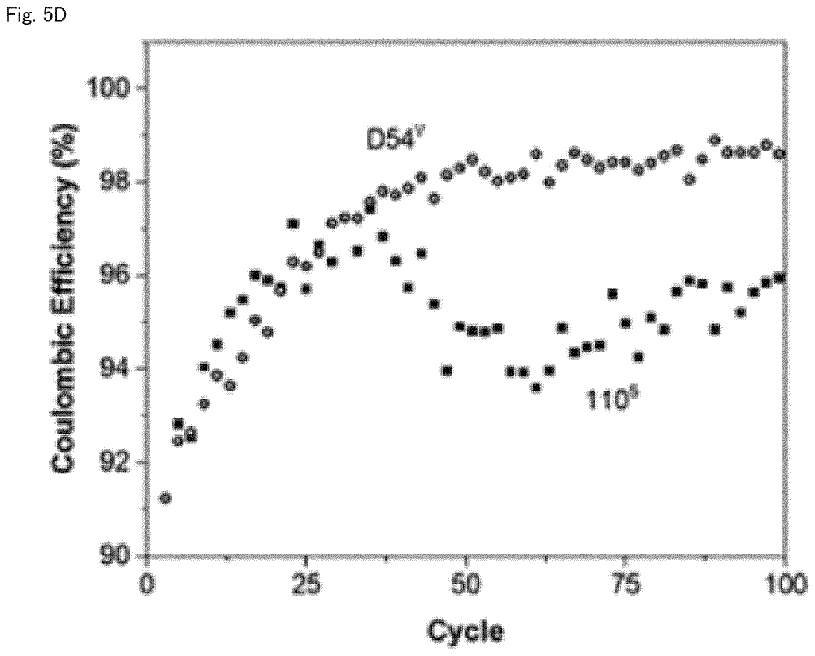

FIG. 5A-5D show comparative electrochemical characterisation of Si films grown on TaNS and Cu foil substrates. FIG. 5A-5B: representative columnar vs. vaulted vs. sedimentary structures; FIG. 5C-5D: single vs. double vaulted structure containing equal amounts of Si. Anodes are assembled in semibatteries using Li foil for reference and counter electrodes, and 1.0 M LiPF₆ in a 50:50 (w/w) mixture of EC:DEC (ethylene carbonate:diethyl carbonate) as the electrolyte. FIGS. 5A, 5C, charge capacity (Si electrode delithiation), and FIGS. 5B, 5D, Coulombic efficiency of semibatteries cycled at 0.5 C between 0.01 and 1V.

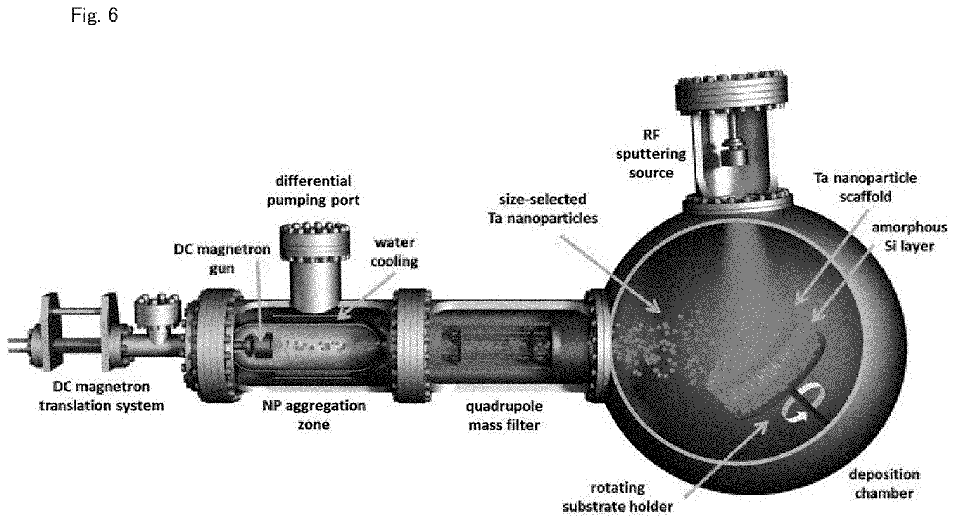

FIG. 6 shows schematic representation of the experimental setup. A sequential deposition of multiple layers of Ta nanoparticle scaffolds (by magnetron-sputtering inert-gas condensation) and overlaid amorphous Si films (by RF-sputtering) resulted in a layered configuration. FIG. 6 is created by Pavel Puchenkov using Blender2.8 (See: www.blender.org).

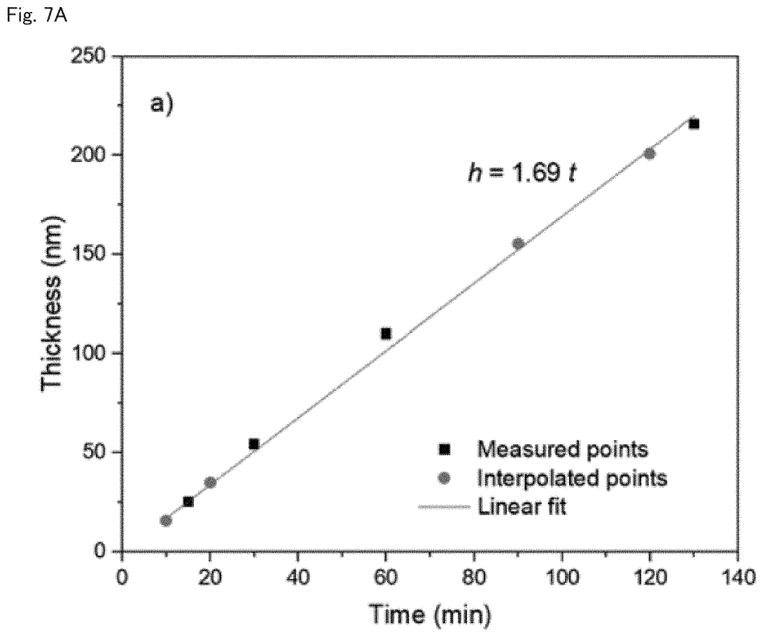

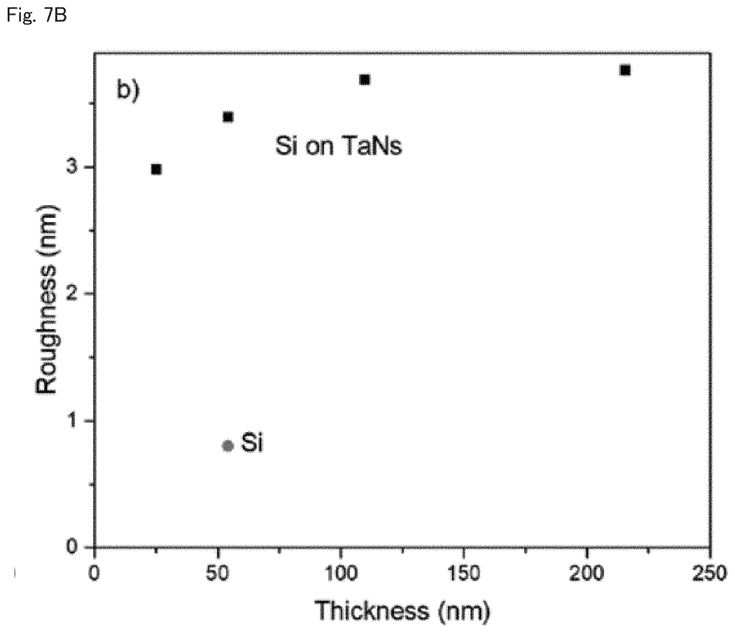

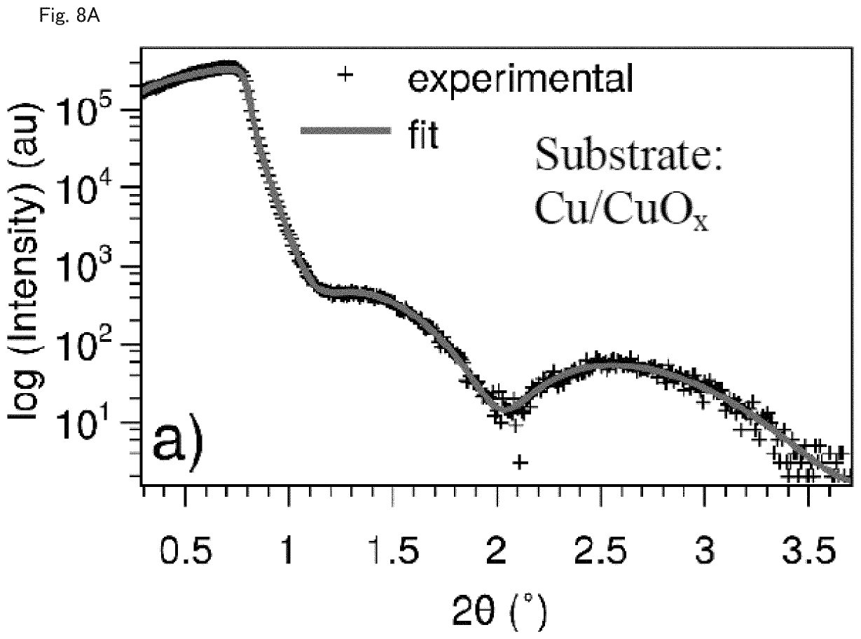

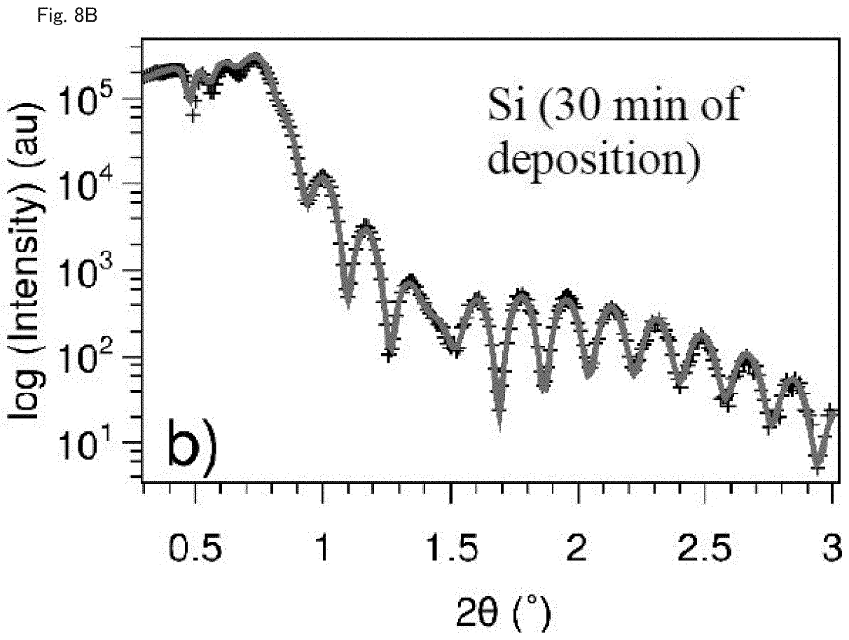

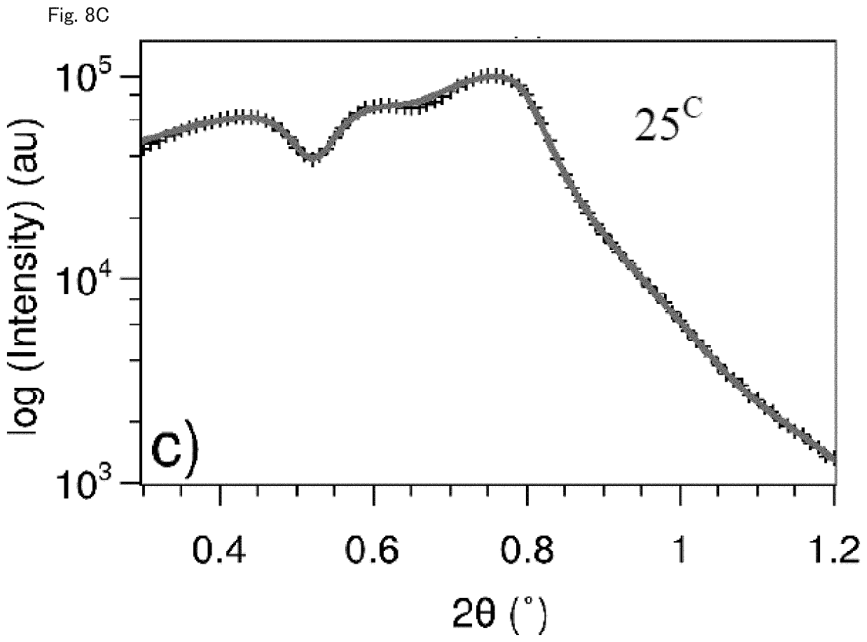

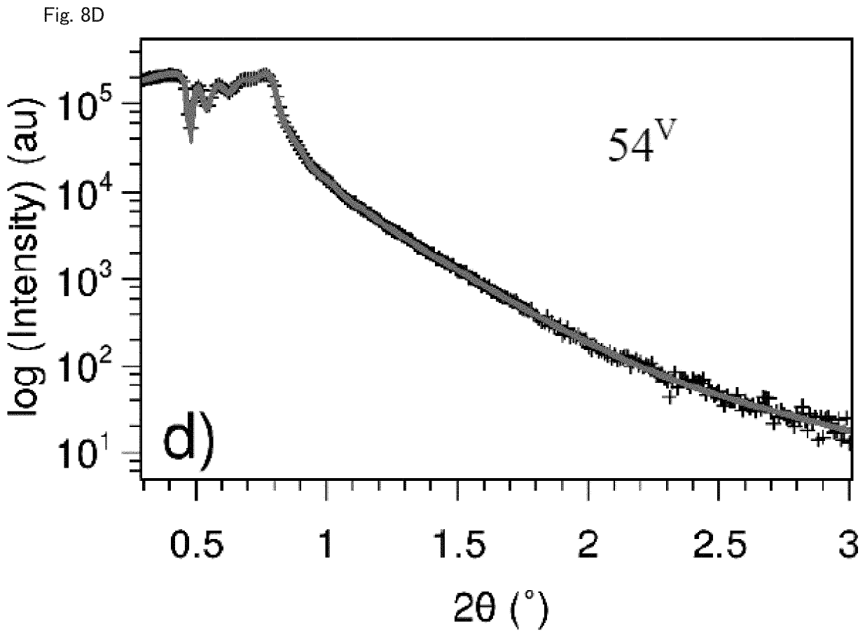

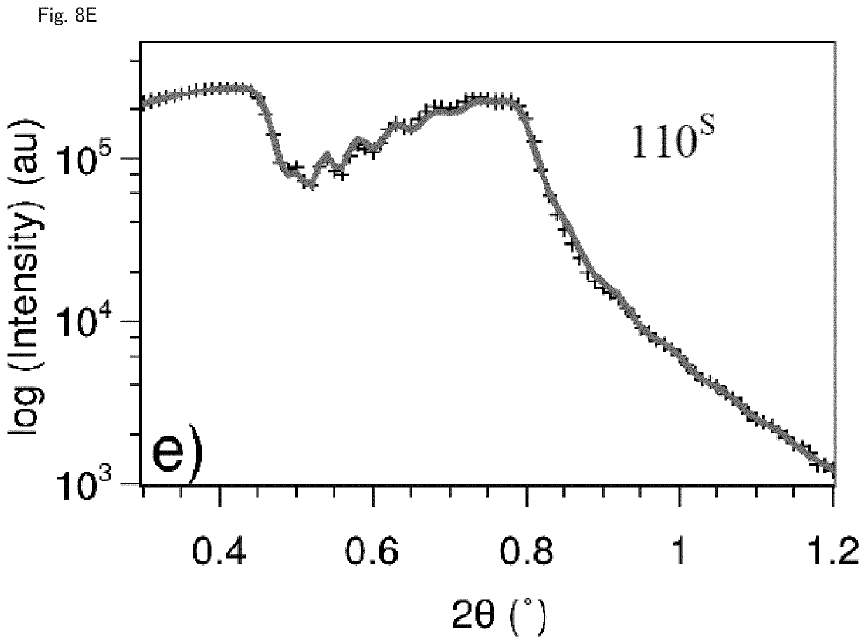

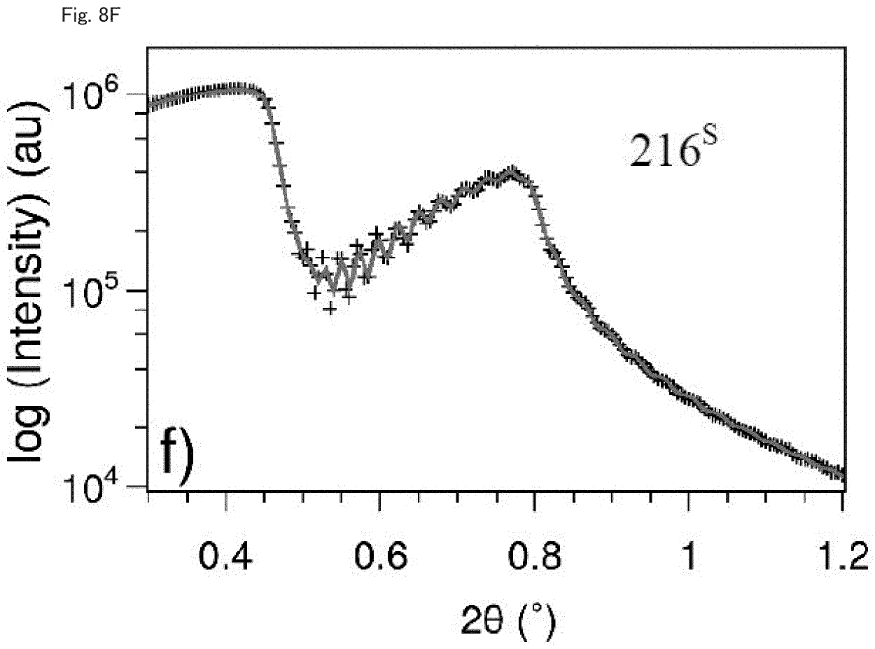

FIG. 7A-7B shows thickness and roughness of Si films deposited on TaNS measured with XRR, for which data and experimental details are provided in FIG. 8A-8F. FIG. 7A shows Si film thickness (h) as a function of sputtering time (t). Square points are measured data and round points indicate interpolated thicknesses at different times. The thickness vs time points conform to the provided linear function. FIG. 7B shows roughness of deposited Si films with different thicknesses.

FIG. 8A-8F show X-ray reflectivity (XRR) measurements of selected samples. The substrate employed for these measurements was Cu (100). XRR measurements were carried out using a Bruker D8 Discover instrument (Bruker AXS GmbH, Karlsruhe, Germany) equipped with Cu wavelength λ=1.54 angstrom X-ray source operated at 1600 W and employing a Goebel mirror. For XRR, the beam was reduced in the reflectivity plane using a 0.05-mm slit in order to minimize the irradiated footprint at the sample position. After careful alignment of the sample, data were collected from 0.2 to 3° (2θ) with a 0.01° step. Experimental XRR data were fitted using GenX 2.4.10 software (v.2.4.10, http://genx.sf.net). In FIG. 8A, a plain Cu wafer surface is modelled, including a native copper oxide layer. In FIG. 8B, Si film growth without pre-deposited Ta nanoparticles show reflection fringes for 2θ>0.8° that are absent for FIG. 8, Si film growth on substrates with Ta nanoparticles. Thus, those fringes belong to a very flat Cu/Si interface that is absent upon deposited Ta nanoparticles. Silicon in FIG. 8B and FIG. 8D used the same Si deposition times. FIG. 8C, FIG. 8D, FIG. 8E, and FIG. 8F, correspond to Si thin-film samples using different Si deposition times.

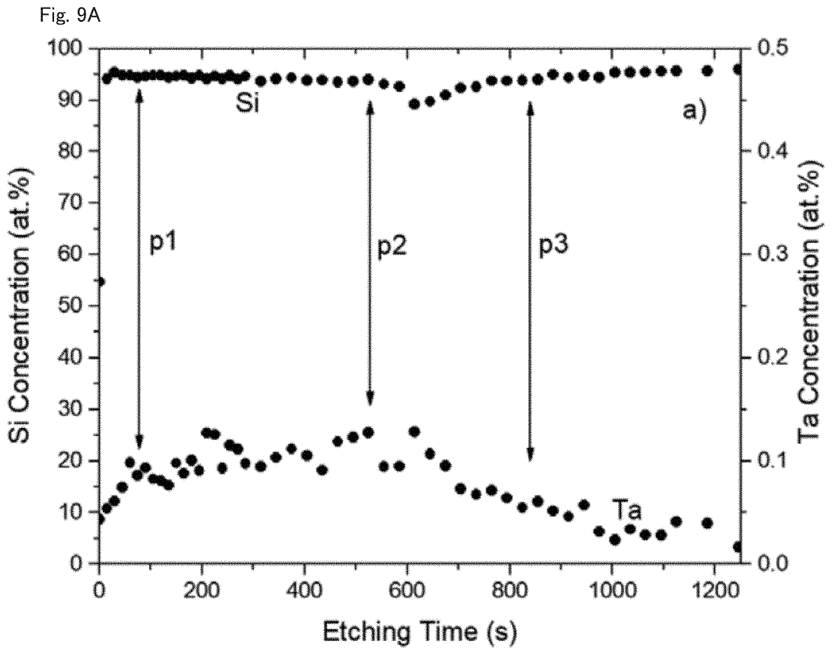

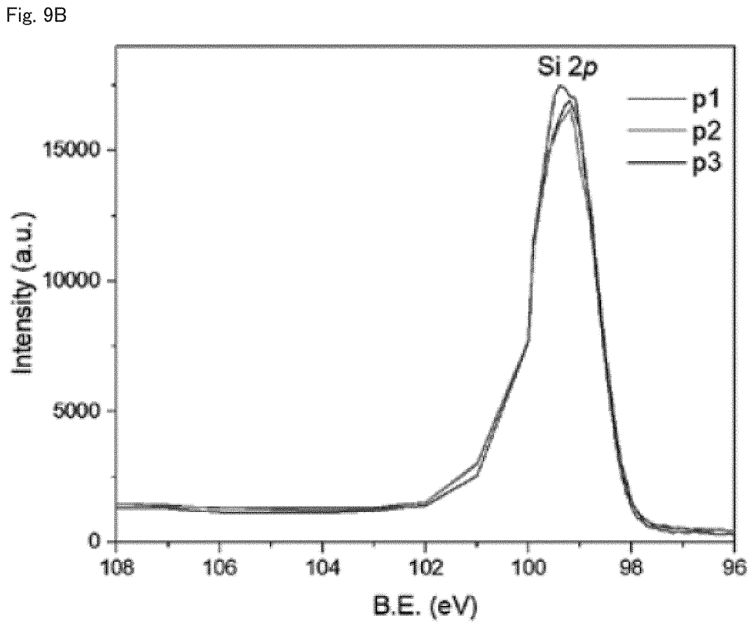

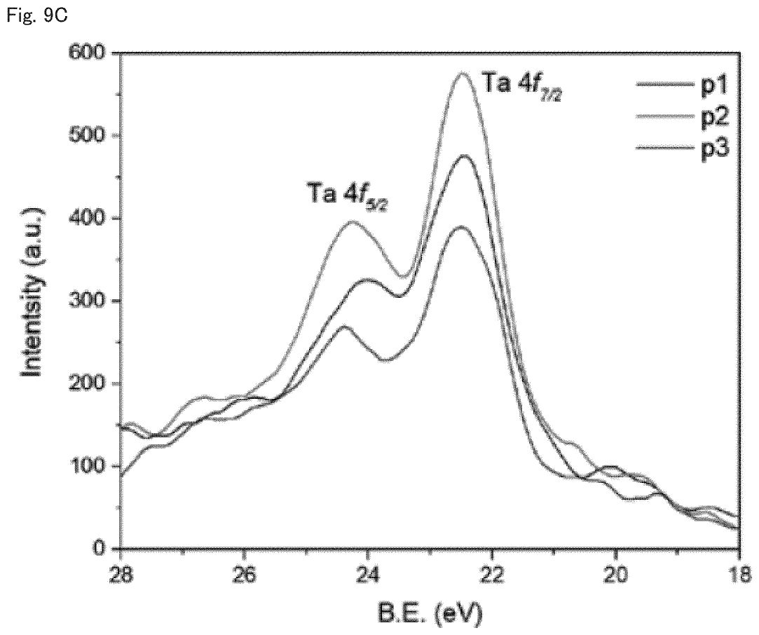

FIG. 9A-9C show estimation of Ta percentage in Si samples using X-ray photoelectron spectroscopy (XPS). For this purpose, a sample with Si and Ta co-deposited for 60 minutes was prepared in a matrix configuration (thickness corresponding to sample 110S). XPS spectra were acquired with a Kratos AXIS Ultra DLD Photoelectron spectrometer, with an Al Ka (1486.6 eV) source and a base pressure of 10-10 mbar. To obtain representative data, XPS measurements were performed at different times of Ar ion etching (ion energy 3 keV). Si and Ta at. % concentrations vs etching times are represented in FIG. 9A, estimated from: FIG. 9B, 2p peak for Si and FIG. 9C 4f for Ta. Si at. % is around 95% while Ta is approximately 0.1%. The difference until sum 100% is 0 and C (present only in the first measurement). Si oxidation can occur during transportation of the sample from the glovebox to the XPS device.

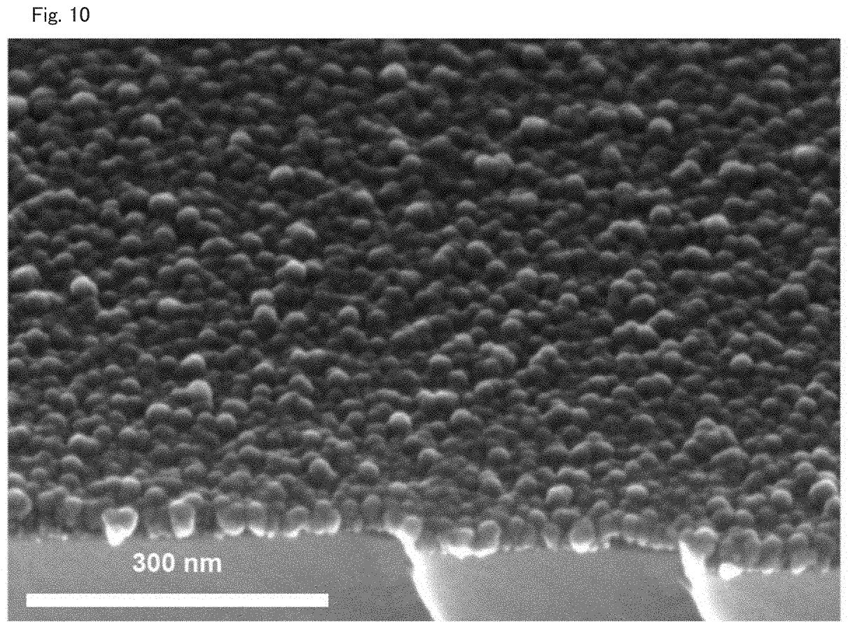

FIG. 10 shows scanning electron microscopy (SEM) cross-section image of sample 25^{C} grown on a Si substrate.

FIG. 11A-11B show effect of the substrate on elastic modulus measurements. Elastic modulus histogram of FIG. 11A, Si sputtered for 60 minutes on the TaNS (sample 110S) and FIG. 11B, Si sputtered for 60 minutes directly on the substrate without nanoparticles. E of the thin films is independent of the substrate when TaNS is present. Alternatively, E strongly depends on the substrate when the deposition is directly on Cu or Si (111). This establishes that, when present, TaNS (and not the substrate) determines the Si growth.

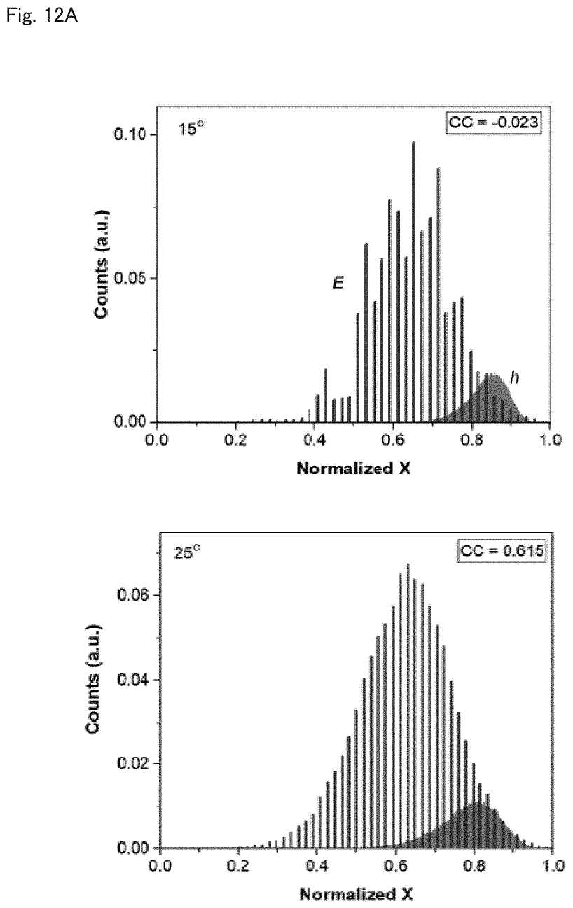

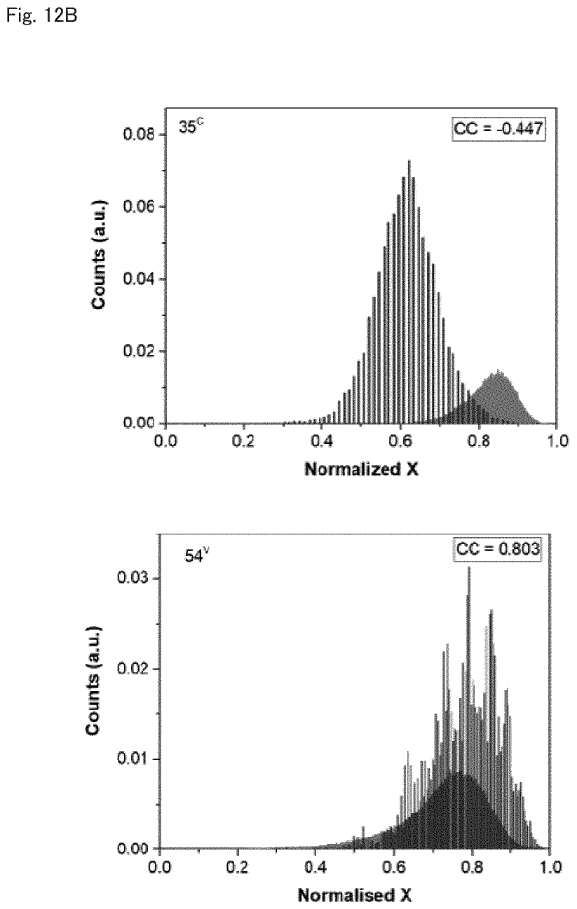

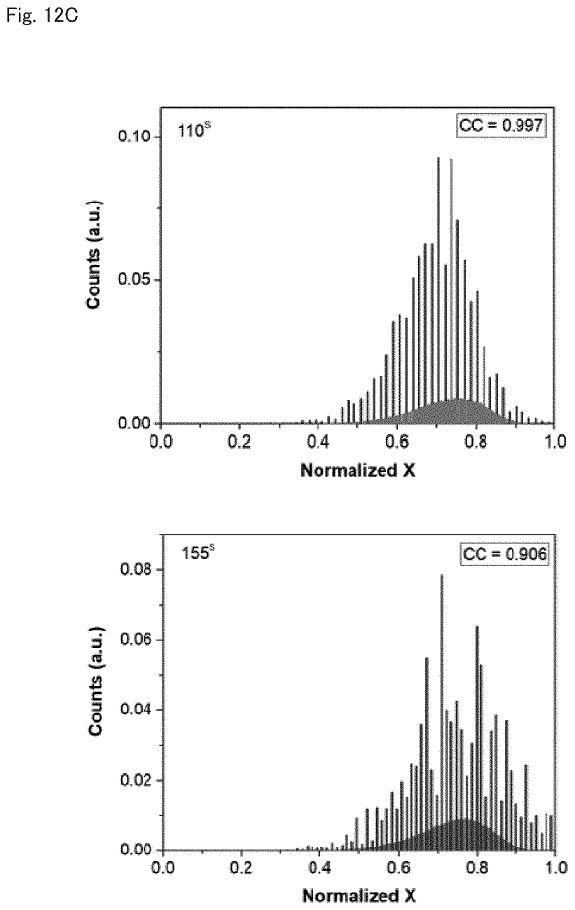

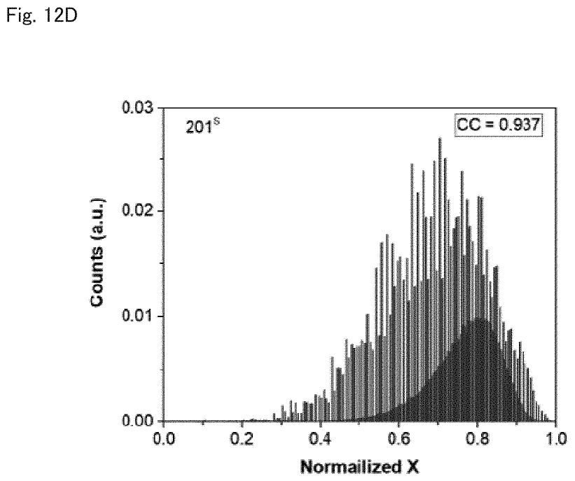

FIG. 12A-12D shows functions of elastic modulus and height for all samples. The correlation coefficient (CC) is indicated inside each graph. The correlation coefficient of random variances X and Y is a dimensionless measure of a linear relationship of X and Y, defined by:

$${ρ}_{X , Y} = \frac{cov ( X , Y )}{{σ}_{X} {σ}_{Y}} = \frac{E [ ( X - {μ}_{X} ) ( Y - {μ}_{Y} ) ]}{{σ}_{X} {σ}_{Y}} \qquad [ Math . 1 ]$$

where cov(X, Y) is the covariance of X and Y, μₓ, μ_{Y}, are the means and σₓ, σ_{Y} are the standard deviations of variables X and Y respectively, provided that the indicated expectation exists. By dividing the product of the means by the product of the standard deviations, the individual variability of each X and Y is removed. The correlation coefficient is always −1≤ρ≤1. A value of 1 implies that the relationship of X and Y can be described perfectly by a linear equation; thus, as X increases, Y increases too. Accordingly, a value of −1 implies that when X increases, Y decreases. If the correlation coefficient is equal to 0, there is no linear relationship between X and Y.

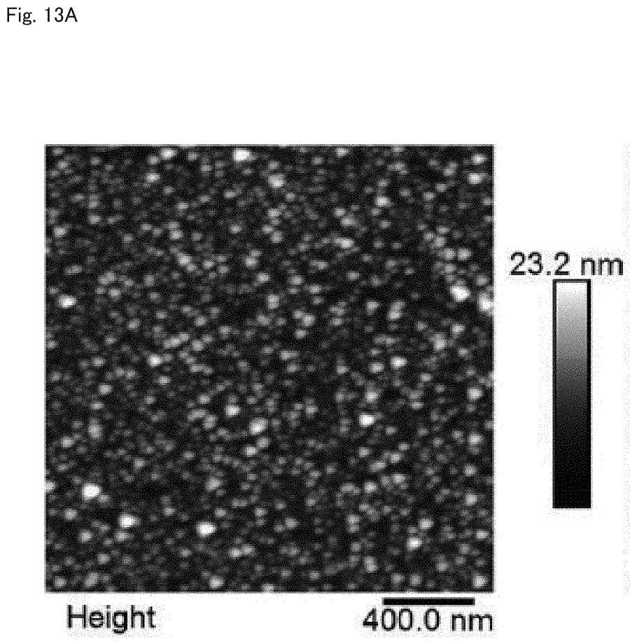

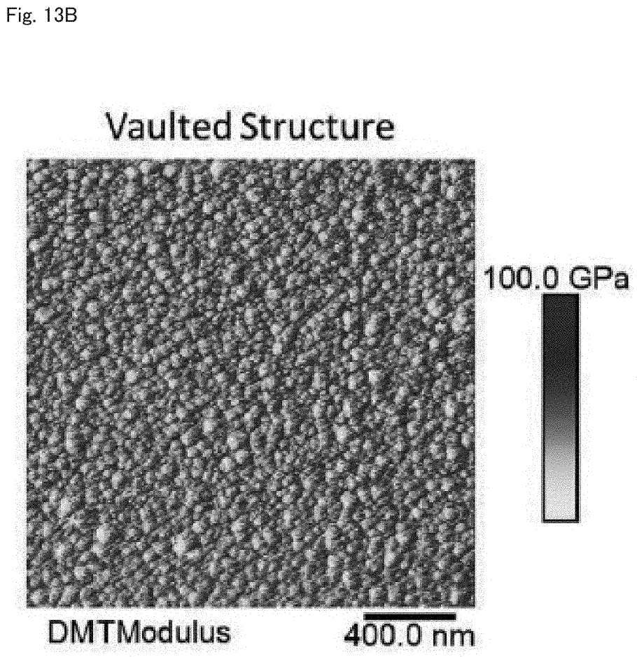

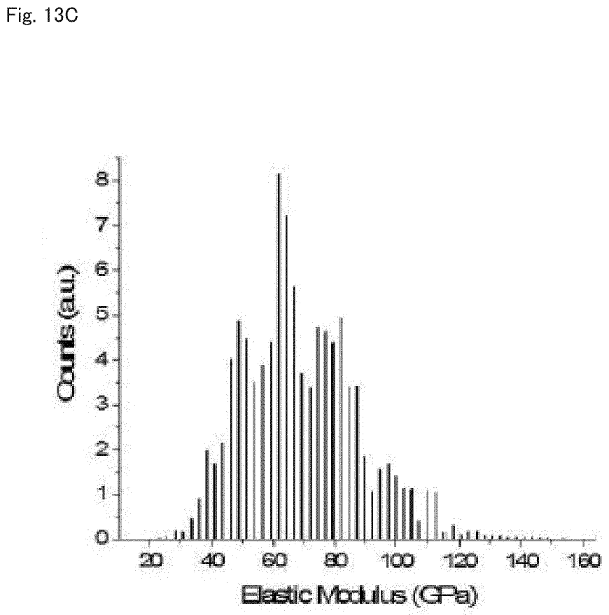

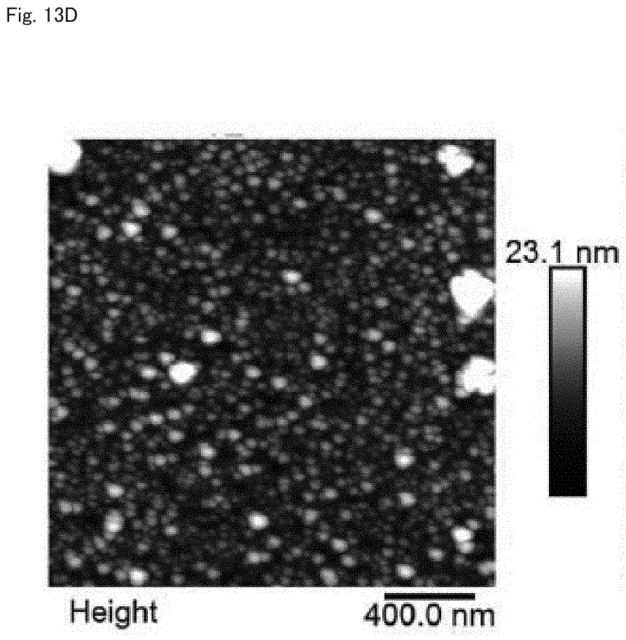

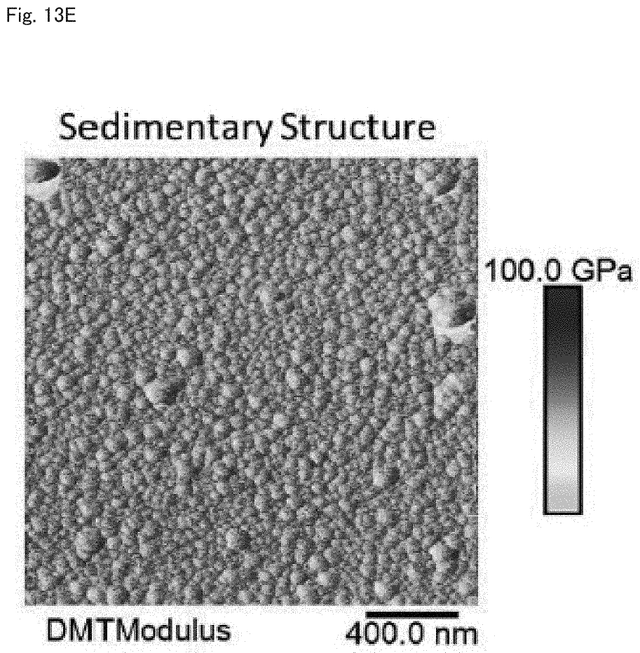

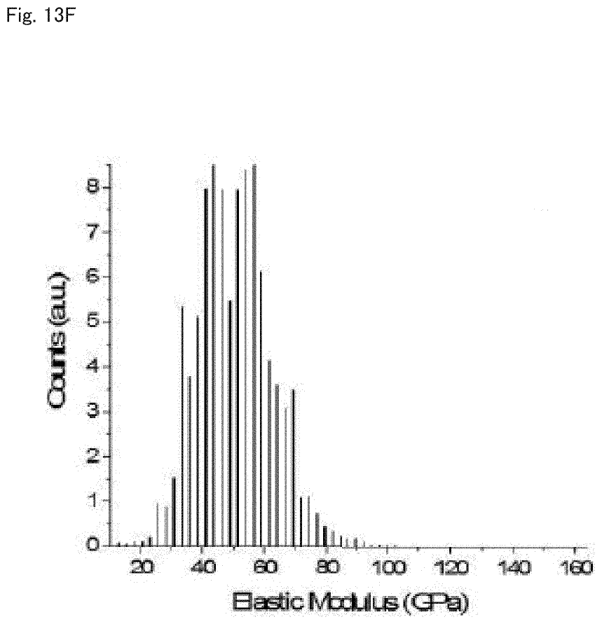

FIG. 13A-13F show mechanical properties of non-annealed samples measured using PF-QNM. The fabrication process of the samples was identical to those of FIG. 3, save for the omission of step 3, i.e., the thermal annealing stage at 150° C. for 60 minutes at Ar pressure of 8×10⁻³ mbar. FIGS. 13A, 13B and 13C show topography, elastic moduli, and histograms of E for exemplary samples of vaulted structure (54^{V}). FIGS. 13D, 13E and 13F show those of sedimentary structure (155^{S}). A significant decrease in E values can be observed for the former (i.e., an average of ˜60-70 GPa) compared to an average of ˜120 GPa for annealed samples. In contrast, there was no discernible effect of the annealing treatment (or the lack of) to the latter, which showed an average value of ˜40-50 GPa, similar to those of the annealed samples. This control experiment confirms the importance of thermal annealing for the strengthening of the vaulted structure through the mobilisation and ensuing eradication of voids, leading towards more rigid individual columns.

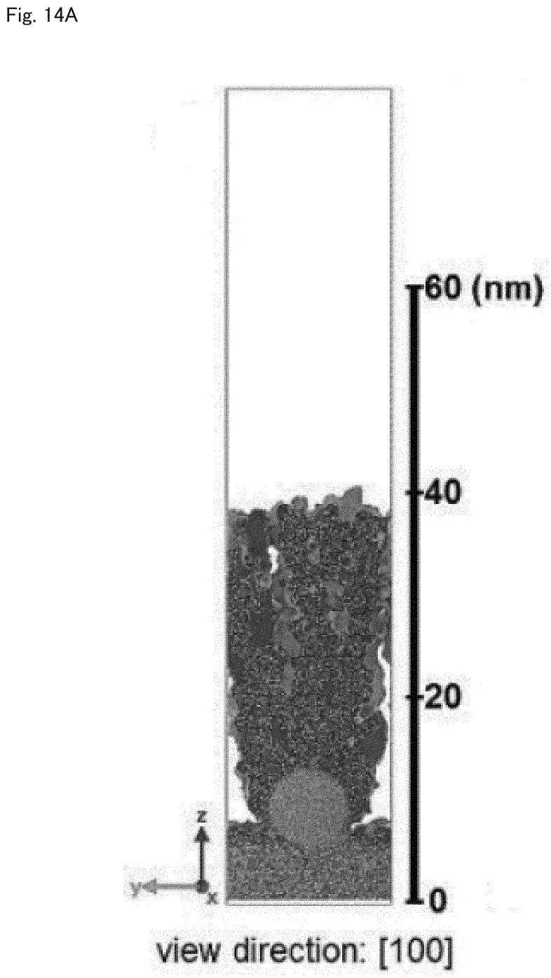

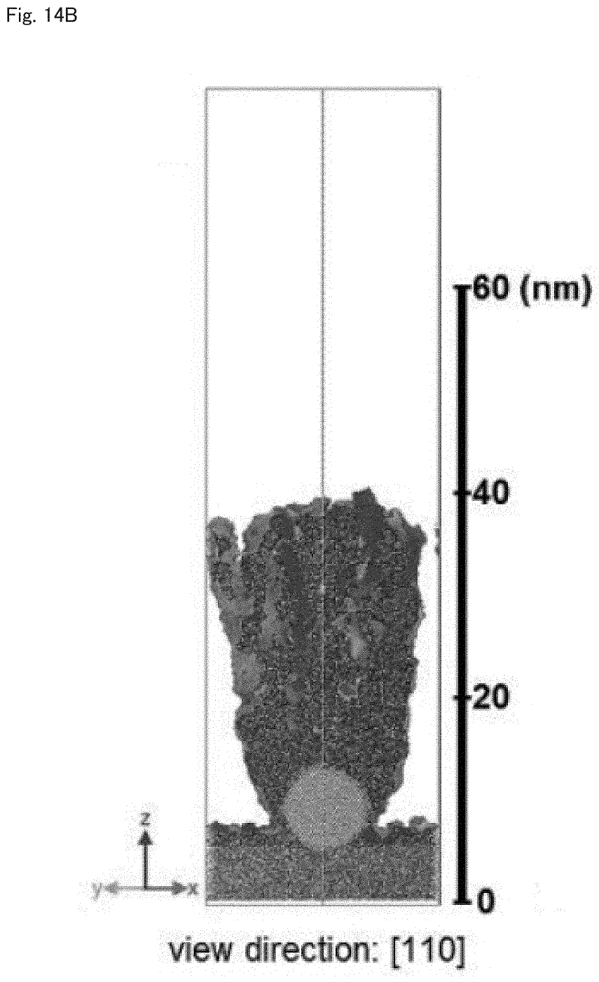

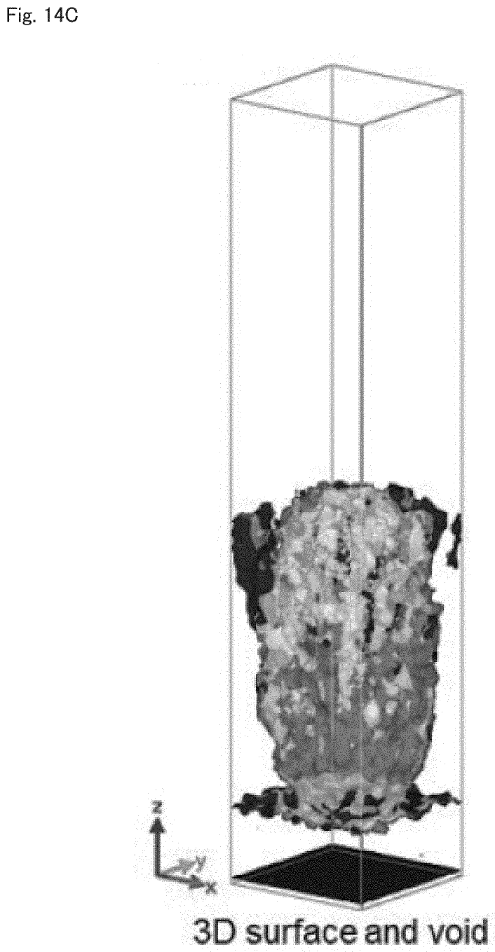

FIG. 14A-14C show Si deposition on a single Ta nanoparticle. Both the simulation box and the nanoparticle are larger than that of FIG. 4A-4F (i.e., 16.4 nm in side length and 8 nm in diameter, respectively) to explicitly study the size effect. Other than that, the setup is identical to that of FIG. 4A-4F (i.e., the simulation box is duplicated along the (100) direction, due to periodic boundary conditions, and the temperature is 500 K). Once again, the Si film follows columnar growth and forms a vaulted structure. The simulation box is sliced for clear observation, viewed along FIG. 14A, the (100), and FIG. 14B, the (110) direction. FIG. 14C, The right panel depicts the surface mesh inside the deposited layer (i.e., without the atoms) in 3D, indicating the presence of voids.

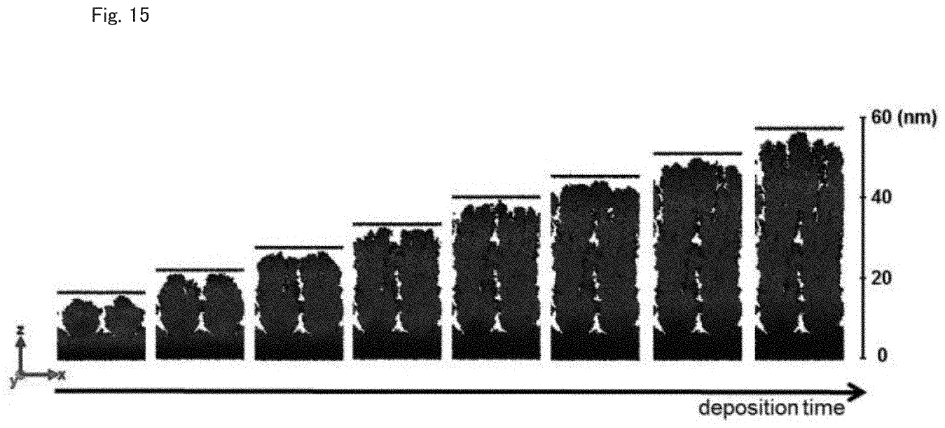

FIG. 15 shows Si deposited on two neighbouring Ta nanoparticles. Two Ta nanoparticles were explicitly introduced in a simulation box twice as long in this simulation group, to avoid the symmetry present in simulations represented by FIG. 4A-4F. Other than that, the setup is identical to that of FIG. 4A-4F (i.e., the simulation box is duplicated along the (100) direction, due to periodic boundary conditions, and the temperature is 500 K). Once again, the Si film follows columnar growth and eventually forms a vaulted and a sedimentary structure. The simulation box is sliced for clear observation, viewed along the (100) direction. Snapshots are taken from a movie, where the evolution of growth can be assessed clearly.

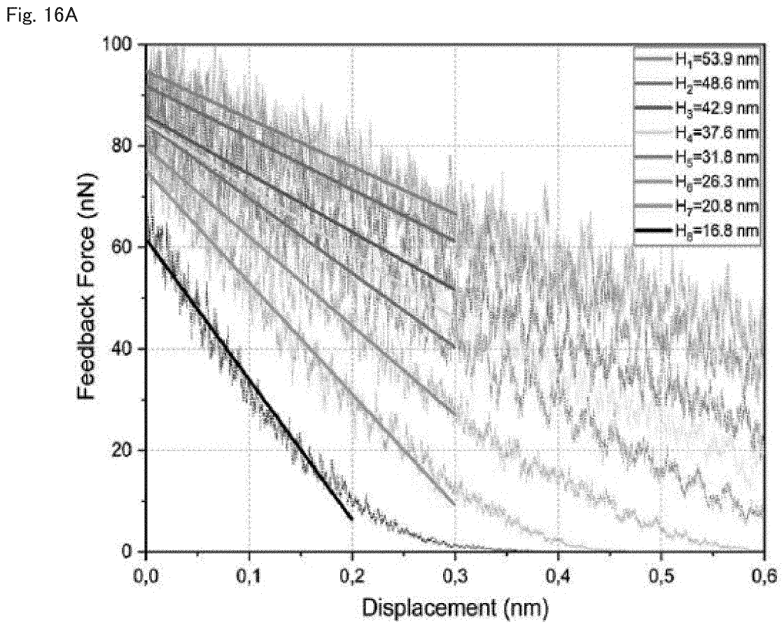

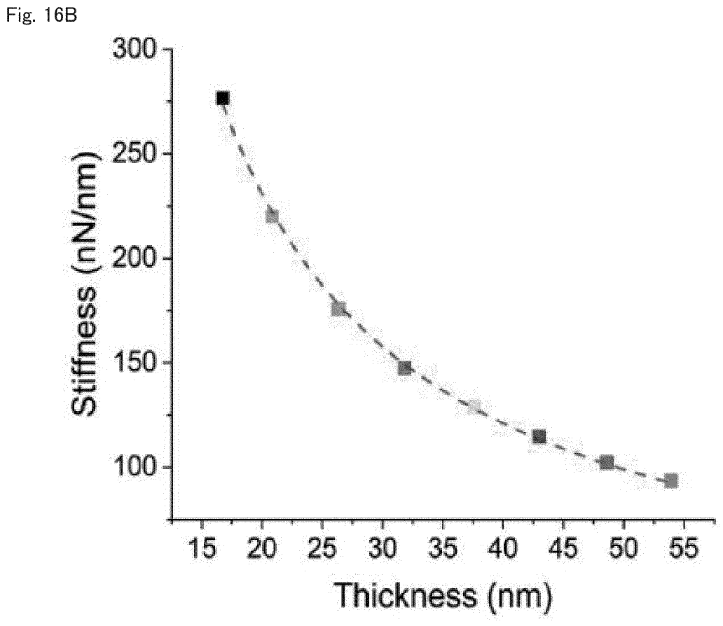

FIG. 16A-16B shows elastic deformation during the unloading process. FIG. 16A. The stiffness of the corresponding structures, as shown in FIG. 4C, is extracted from the slopes of the linear fitting lines of the curves (solid lines). FIG. 16B, The decompression stiffness as a function of structure thickness drops in a monotonous fashion, unlike that during the loading process. The red dashed curve shows the non-linear fitting from Math. 2, below.

Validation of the porosity value provided by MD:

The porosity of the deposited amorphous silicon structure is strongly affected by the sputtering conditions and temperature, as such parameters determine adatom mobility. The porosity obtained through our MD simulations can be estimated by comparing the number density of Si atoms in a porous structure whose volume can be measured from the surface construction analysis, with a reference number density for a bulk amorphous silicon sample. Such analysis resulted in a porosity value of ˜0.3.

In the elastic regime, the deposited structure can be approximated by a spring, the stiffness of which is inversely proportional to the length:

$$S = \frac{AE}{L} \qquad [ Math . 2 ]$$

where A is the cross-section area, E is the modulus of elasticity, and L is the length. For this structure, the cross-section area A is 10.89 nm×10.89 nm. The relation between the modulus of elasticity and the porosity was studied extensively. The estimation is

E=E₀(1−p)² [Math. 3]

where p is the porosity; therefore, from the unloading stiffness, we can calculate the bulk Young's modulus E₀ as 75 GPa, which is in good agreement with the literature value, thus validating our method.

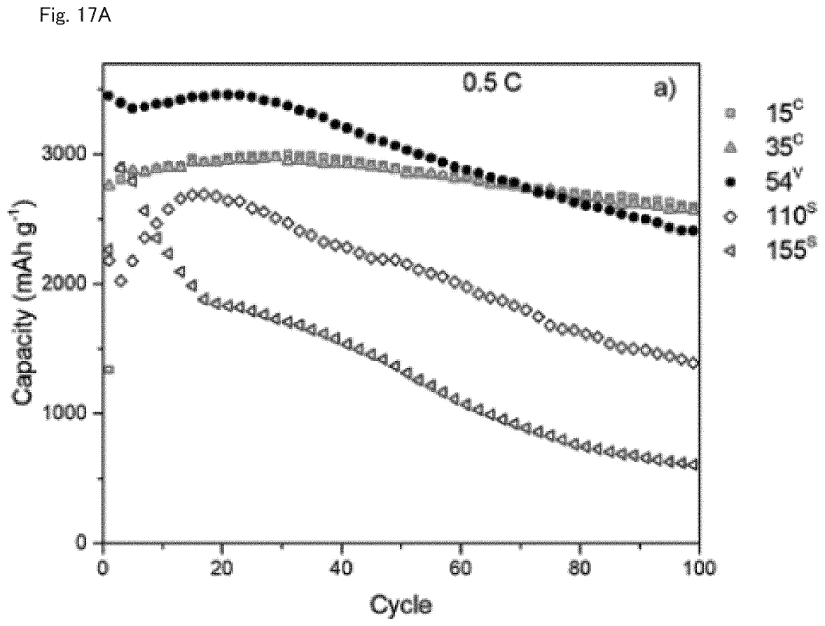

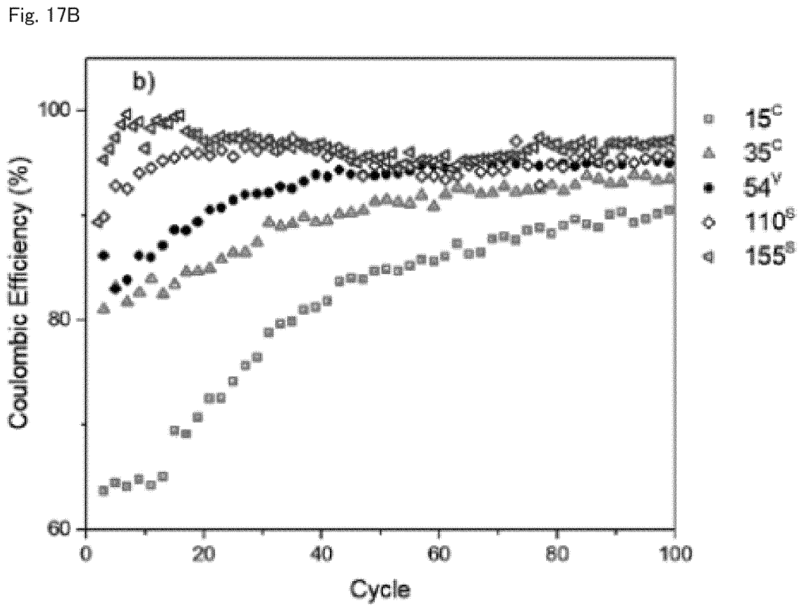

FIG. 17A-17B show LIB performance of Si samples showing different behaviours according to the structure and E characteristics. FIG. 17A shows charge capacity (Si electrode delithiation), and FIG. 17B shows Coulombic efficiency.

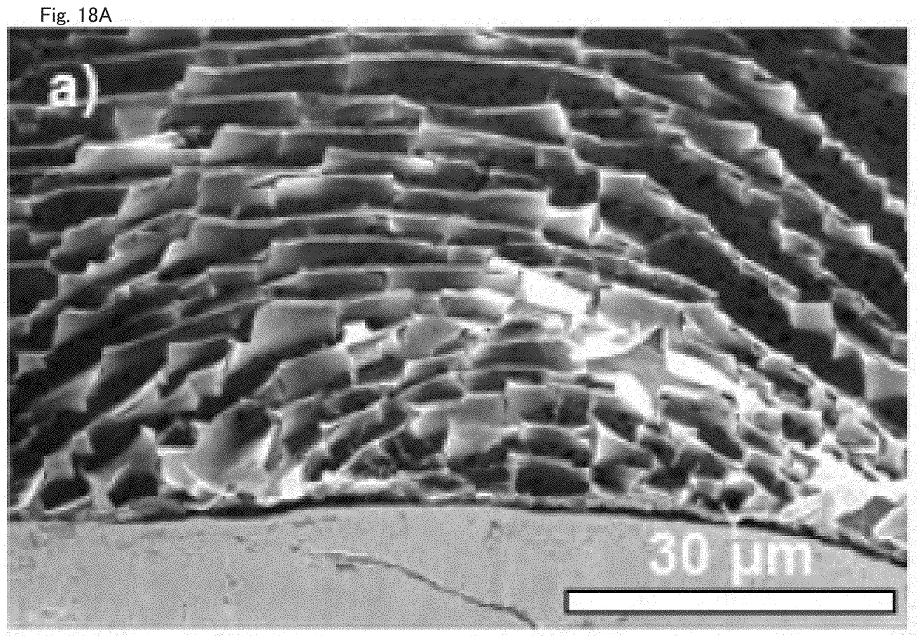

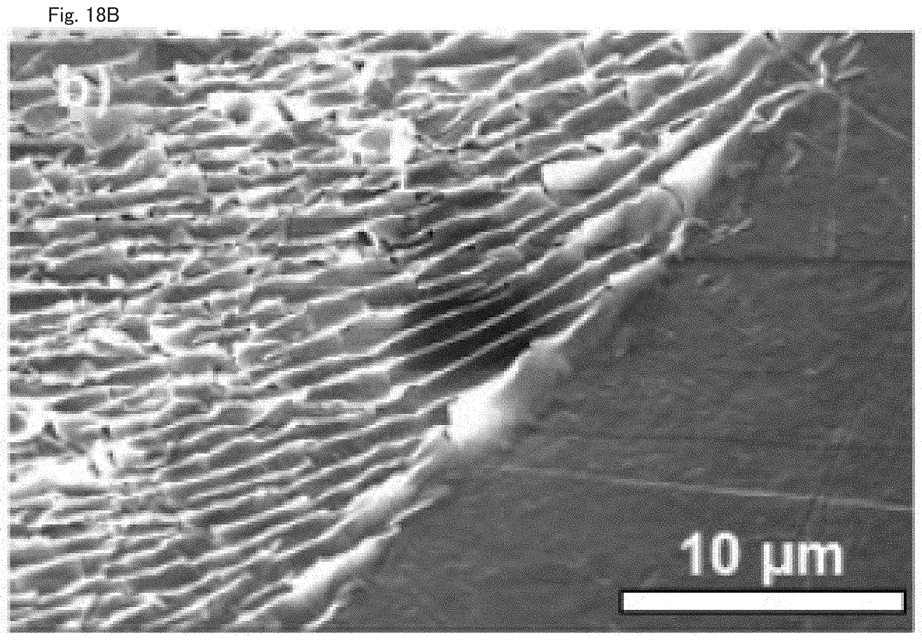

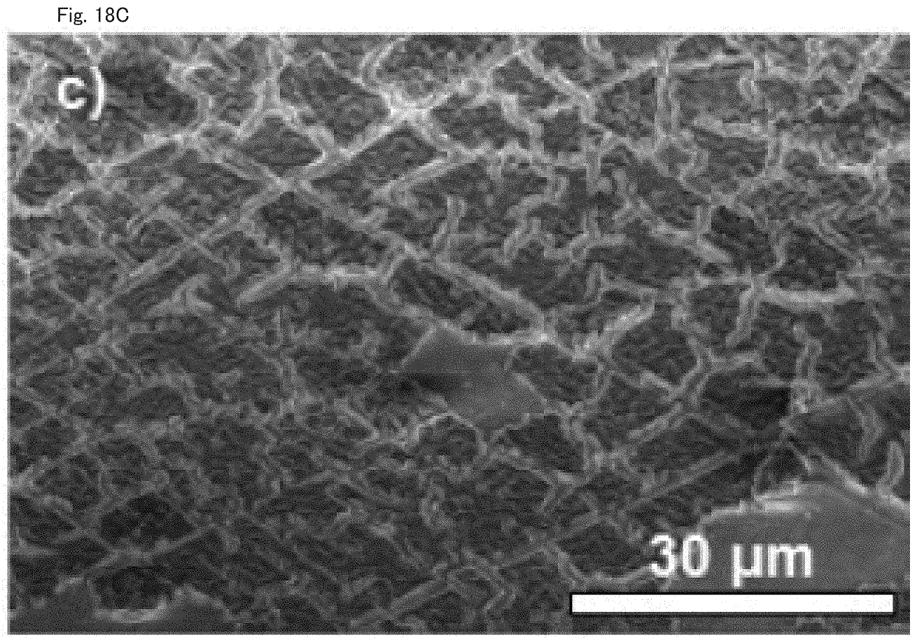

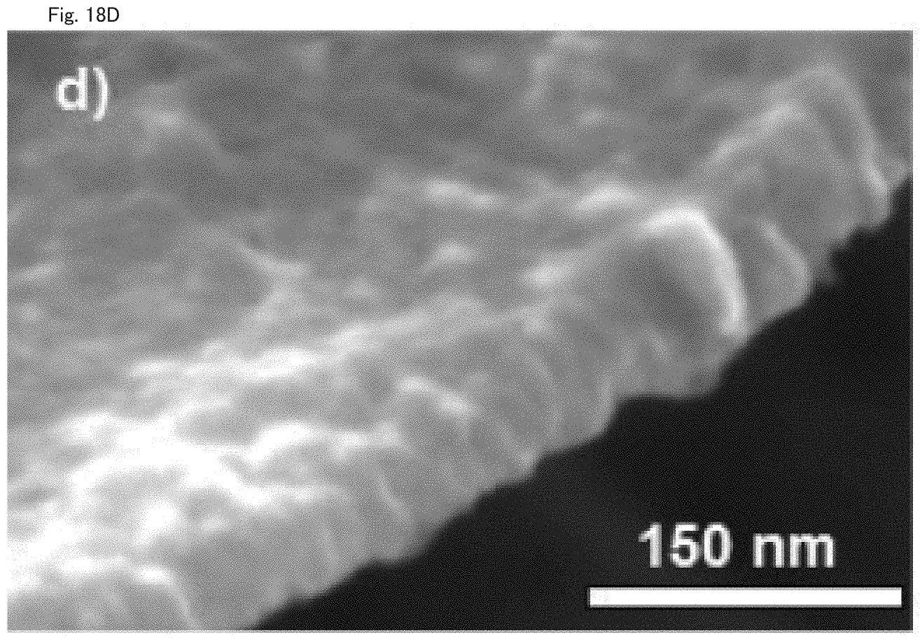

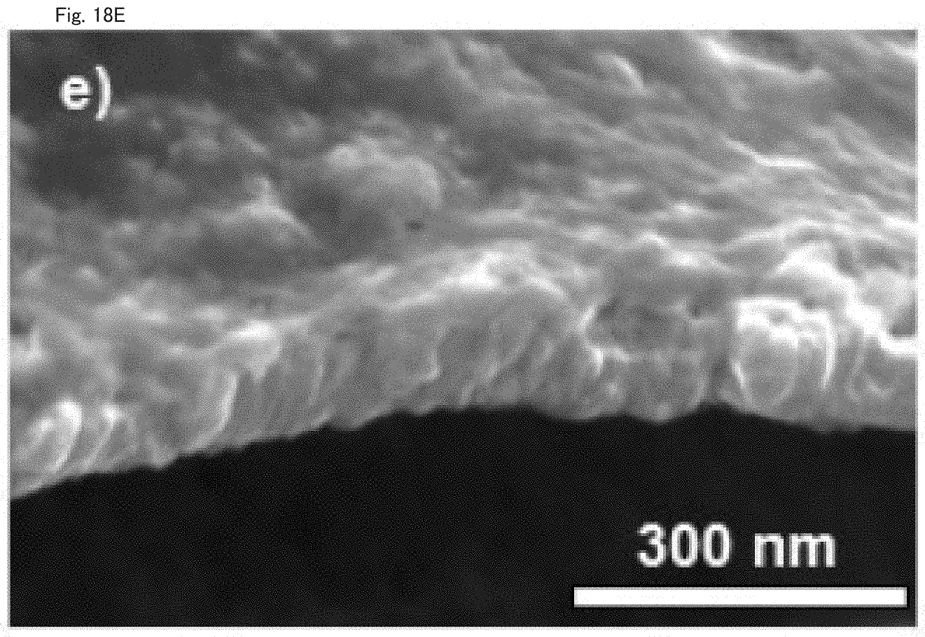

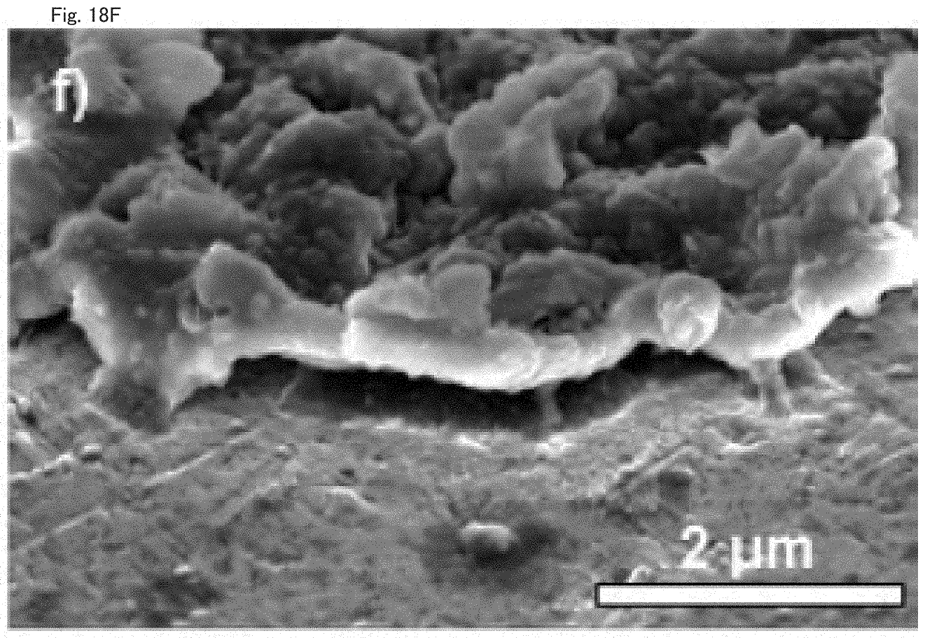

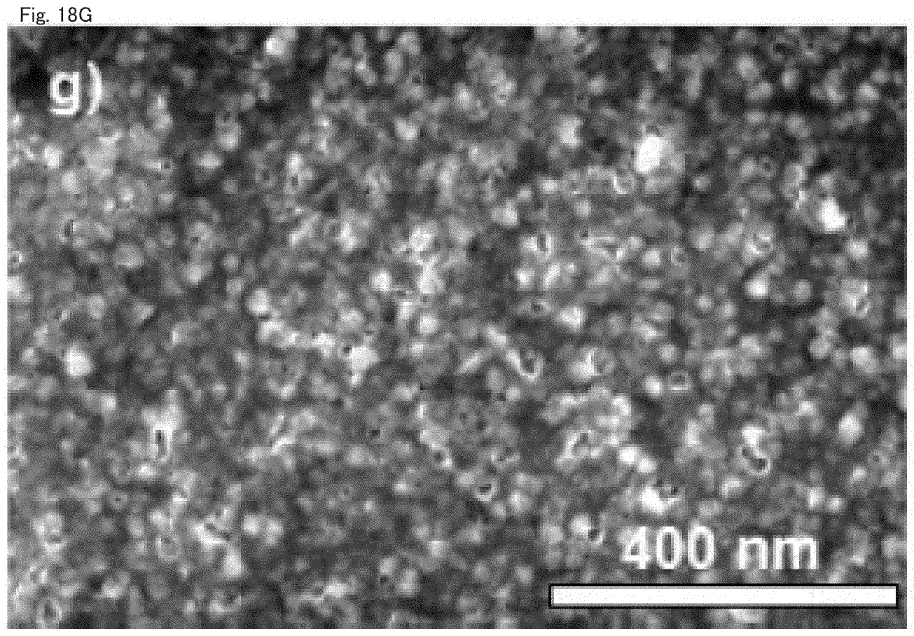

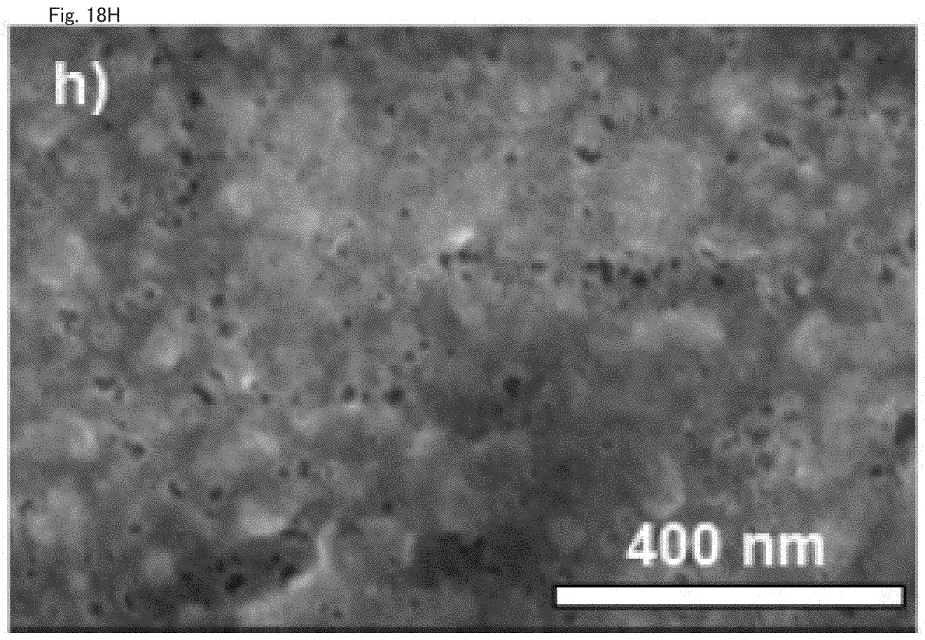

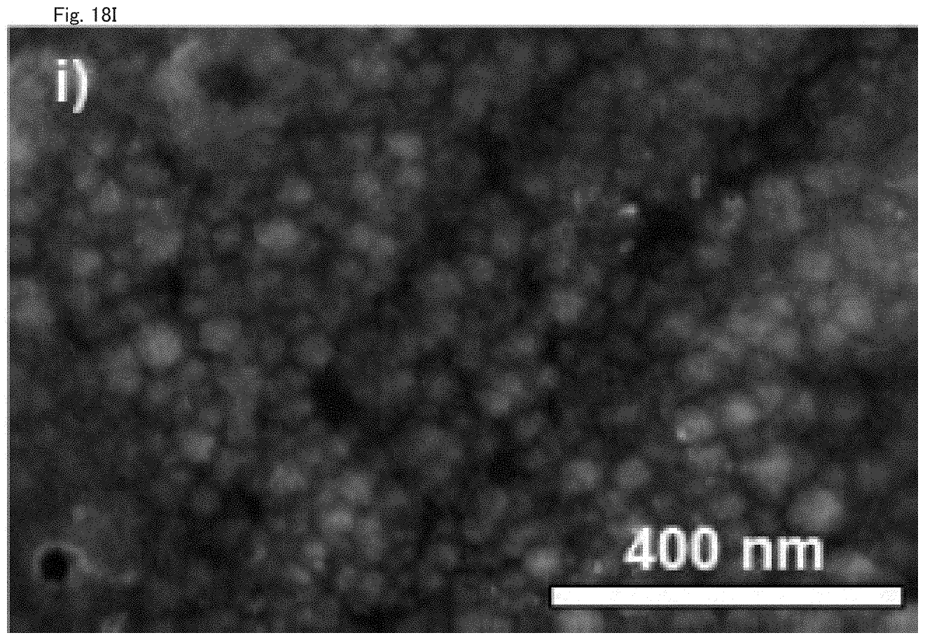

FIG. 18A-18I are SEM images of samples 15^{C} (FIG. 18A, 18D, 18G), 54^{V} (FIG. 18B, 18E, 18H), and 155^{S} (FIG. 18C, 18F, 18I) after three charge-discharge cycles at 0.5 C between 0.01 and a 1 V. Imaging the physical condition of electrodes after cycling can help explain their electrochemical behaviour. Once the electrodes were delithiated, the semibatteries were opened inside the Ar glovebox and the anodes cleaned with dimethyl carbonate and dried in high vacuum. Low magnification images (FIG. 18A-18C) show the ripples formed on 15^{C} and 54^{V} by a diamond pen scratch; similar scratching was not necessary for sample 155^{S}, which shows a highly cracked film forming islands. Cross-sections (FIG. 18D-18F) show the columnar and vaulted structure at the edge of the ripples, and a detached film at the edge of the cracked island for sample 155^{S}. This can attribute the high Coulombic efficiency concurrent with the high capacity fade observed for 155^{S}, not to exposure of fresh electrode to electrolyte, but, instead, to loss of active material. Top-down, high-magnification images of the cycled anodes (FIG. 18G-18I) show the formation of holes. The holes are especially prevalent in the 15^{C} and 54^{V} structures, and can be attributed to channels created by the electrolyte during cycling, most likely associated with the activation phenomenon (during activation more active material is involved in the lithiation process during cycling).

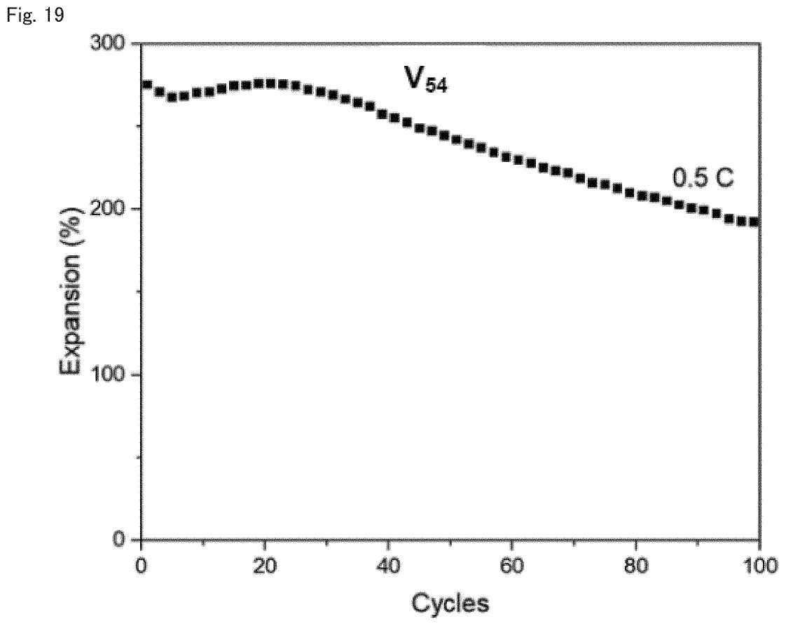

FIG. 19 shows volume expansion of the electrode 54V in a lithium semibattery at 0.5 C, estimated according to V. L. Chevrier et al (V. L. Chevrier, L. Liu, D. B. Le, J. Lund, B. Molla, K. Reimer, L. J. Krause, L. D. Jensen, E. Figgemeier, K. W. Eberman J. Electrochem. Soc. 2014, 161, A783).

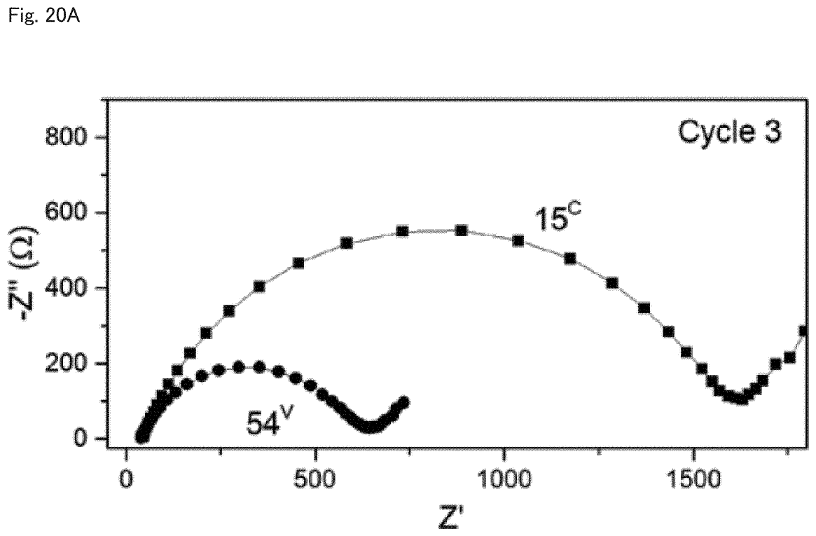

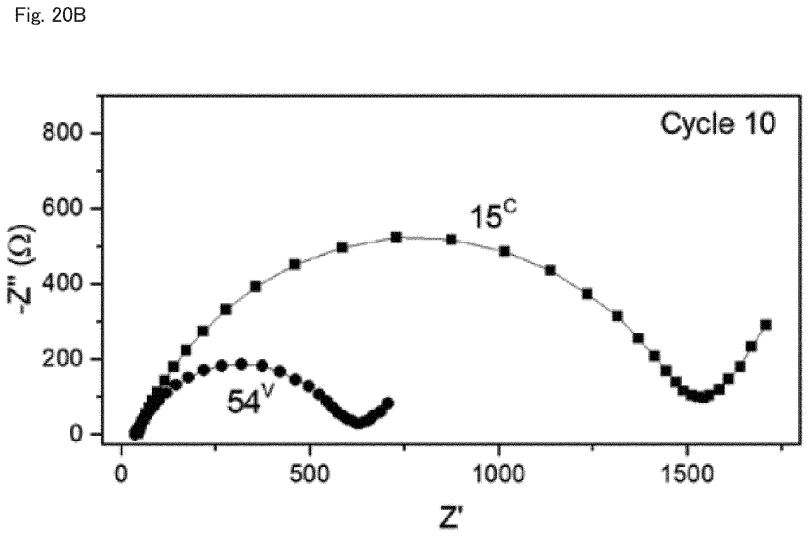

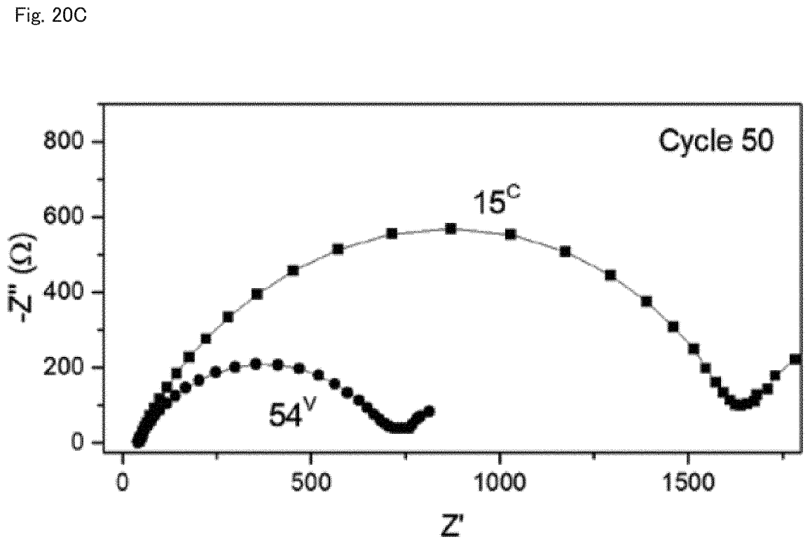

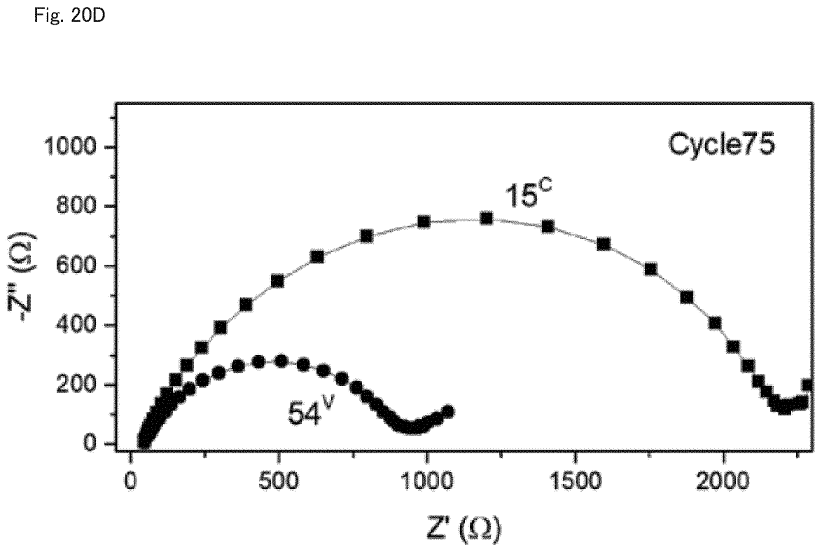

FIG. 20A-20D show Nyquist plots of 54^{V} and 15^{C} registered at an open circuit after several cycles. The resistance at high frequency is associated with the electrode/electrolyte interfacial resistance (SEI and the charge transfer), and it is three times higher for 15^{C} than for the 54^{V} sample. This confirms that the higher electrode/electrolyte interface in the columnar structure is responsible for the larger SEI.

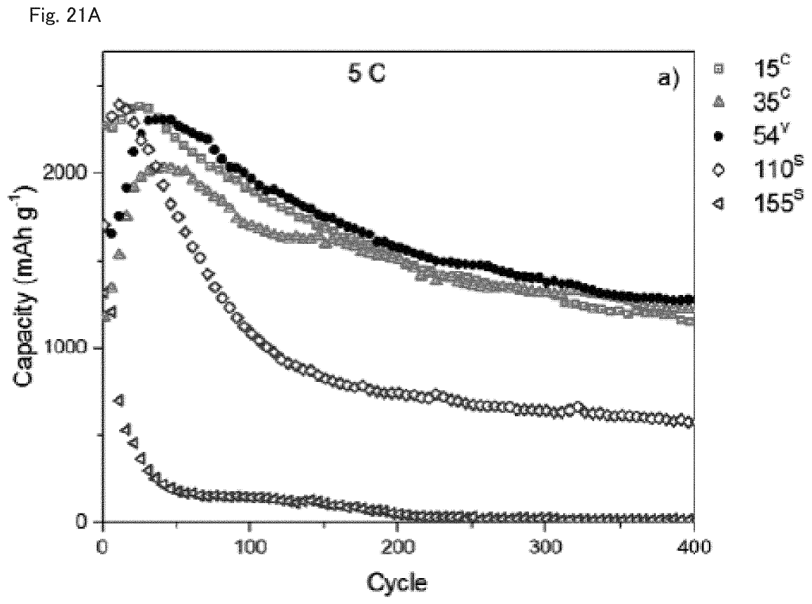

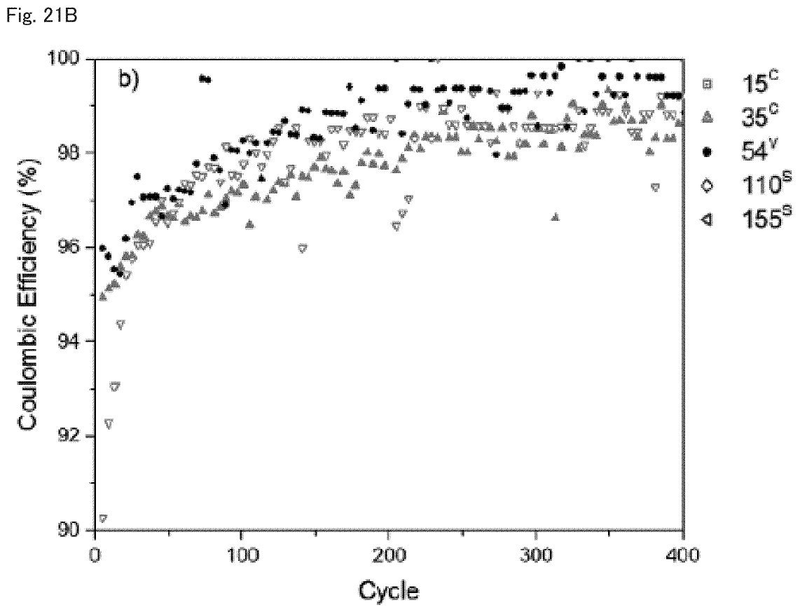

FIG. 21A-21B show LIB performance of Si samples showing different behaviours according to the structure and E characteristics. FIG. 21A, Charge capacity (Si electrode delithiation) and FIG. 21B, Coulombic efficiency. The values are close to 100%, but they are not significant because the capacity fade suggests the sample becomes fractured.

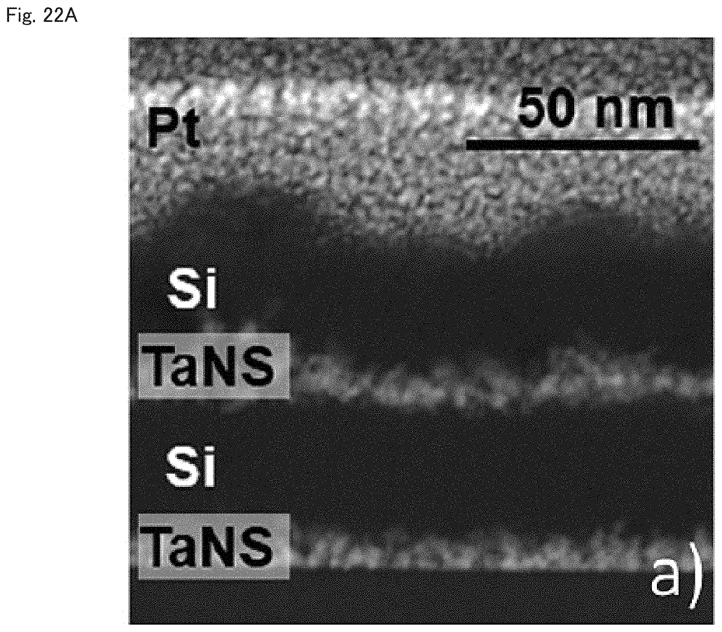

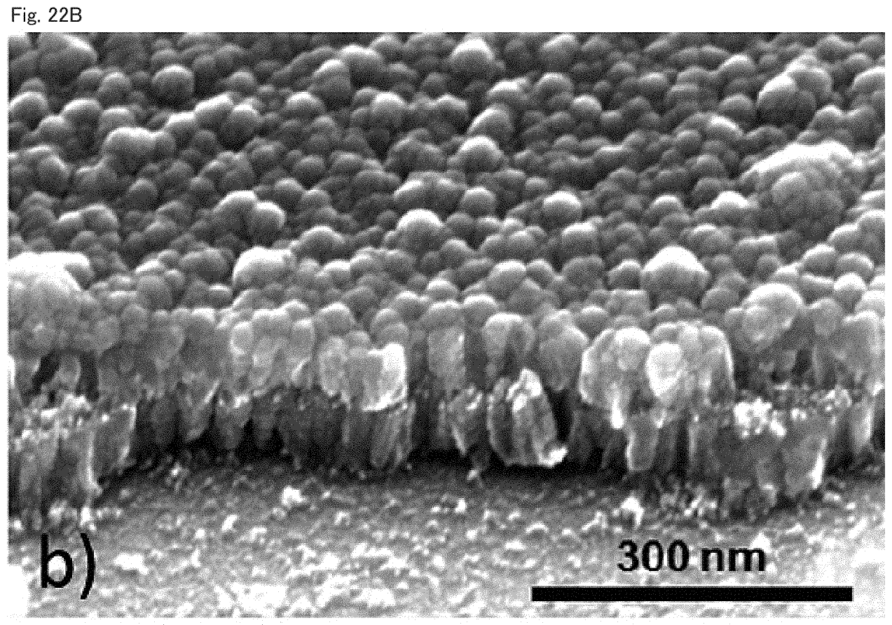

FIG. 22A-22B show characterisation of D54^{V} sample grown on Si substrate before lithiation-delithiation cycling. FIG. 22A, TEM lamella image, FIG. 22B, SEM image. A double-vaulted structure is evident instead of a sedimentary structure fabricated with the same amount of Si and a single TaNS (110^{S}).

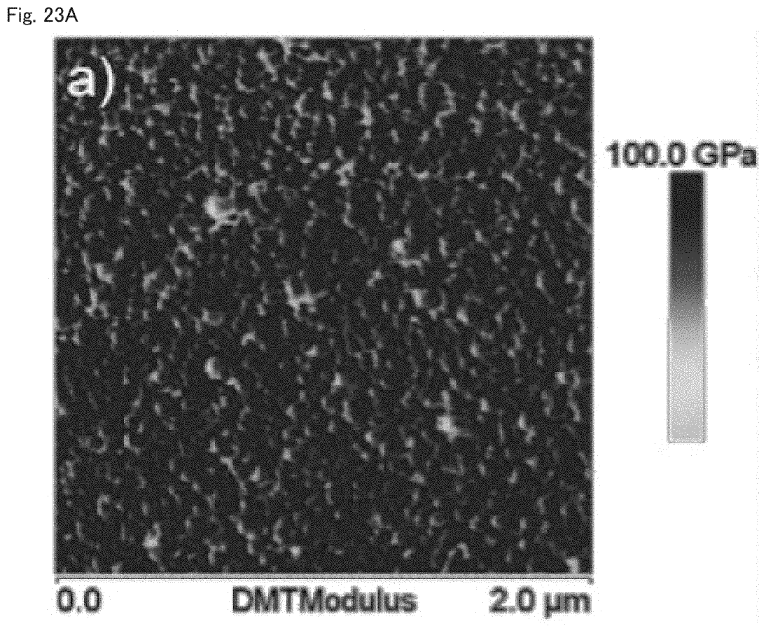

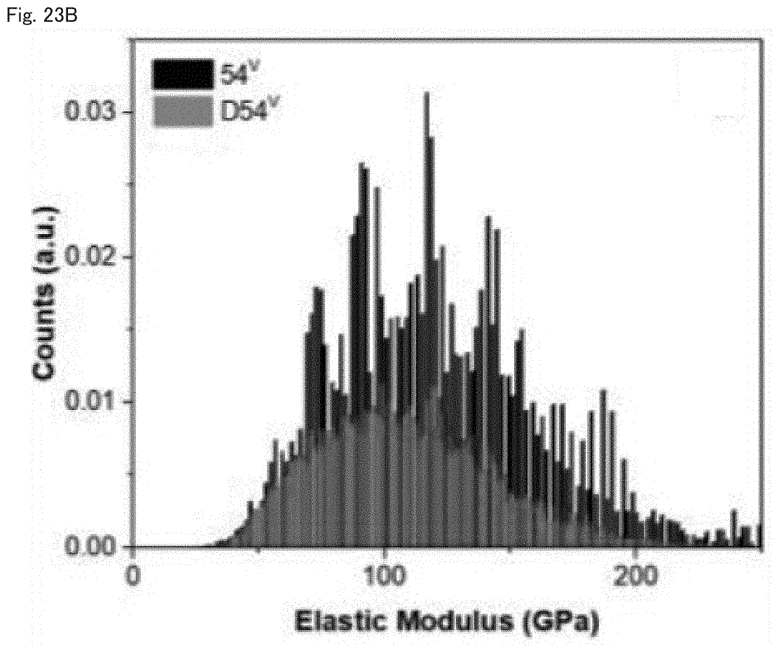

FIG. 23A-23B show mechanical properties measured using PF-QNM of the D54^{V} sample. FIG. 23A, Elastic modulus (most of the mapping is saturated because the scale is the same as the scale used in FIG. 3), and FIG. 23B, corresponding histogram. The histogram shows a comparison between the D54^{V} and 54^{V} samples.

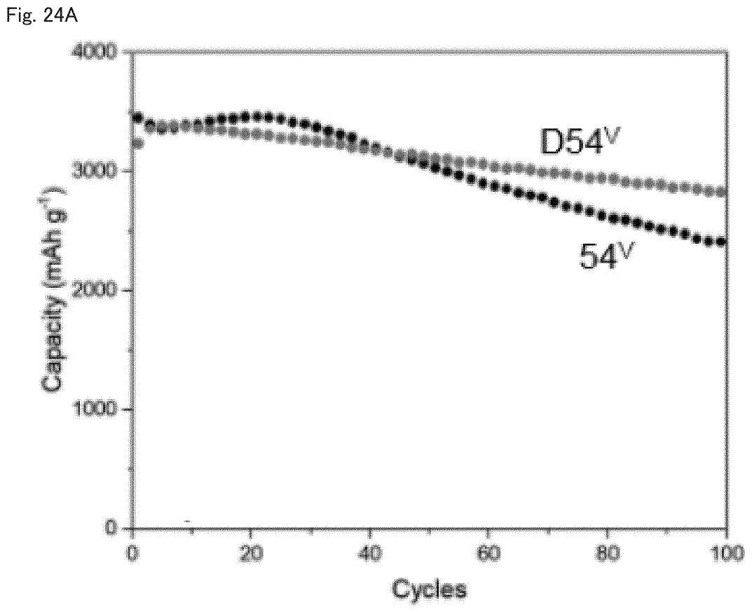

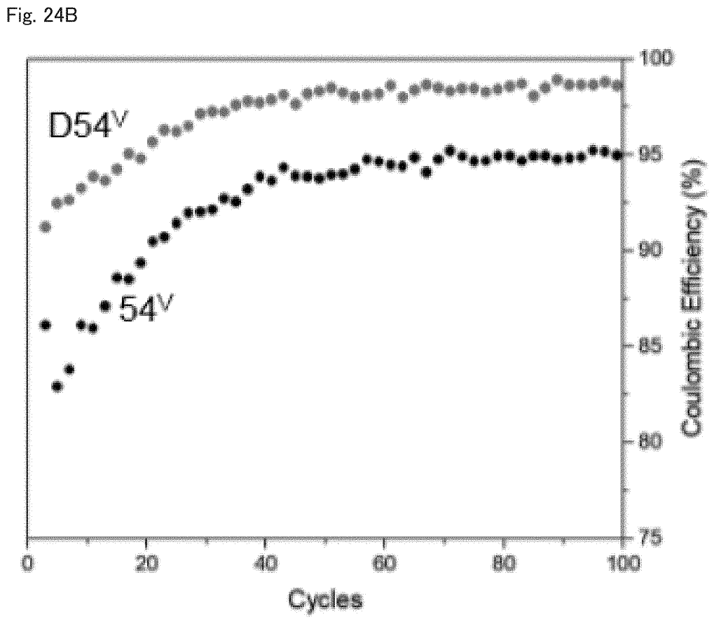

FIG. 24A shows charge (delithiation) capacity of LIB semibatteries cycled at 0.5 C for D54^{V} and 54^{V} samples, and FIG. 24B shows Coulombic efficiency of the same samples.

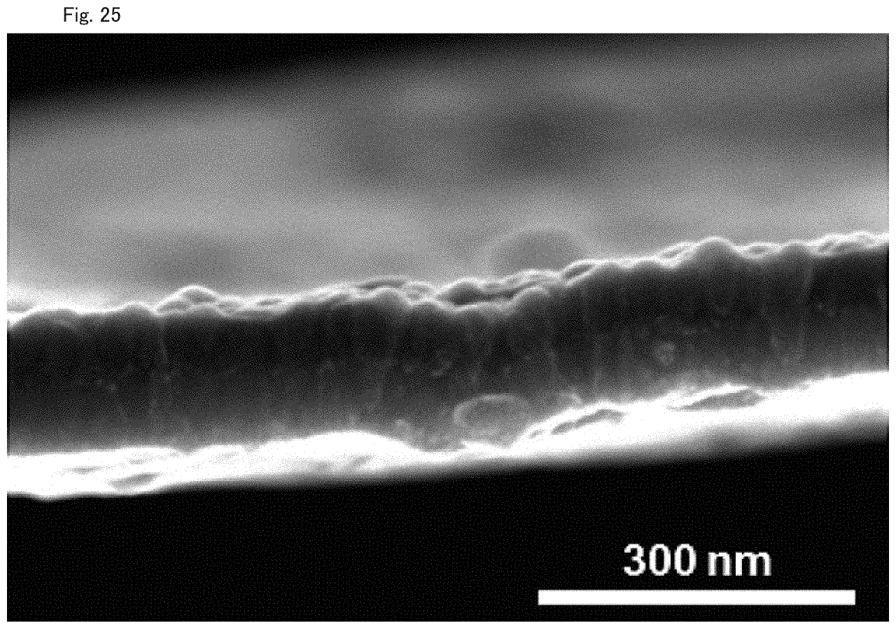

FIG. 25 is a SEM image of sample D54^{V} after three lithiation-delithiation cycles. The sample was grown on a Cu foil so that the anode could work in a semibattery. The bilayer structure is retained after charge-discharge cycling.

### <3. Overview of Design Strategy and Vaulted Structure Concept>

Samples were grown directly on substrates by sequential and independently controlled cluster beam deposition (CBD) of Ta nanoparticles and RF sputtering of Si thin films (FIG. 6). This setup enables the fabrication of binder-free, high-purity films (grown in high-vacuum conditions) with good control over thin-film thickness and nanoparticle size and shape. First, crystalline Ta nanoparticles were deposited (FIG. 1A, step 1), forming a porous nanoparticulated film that acted as a nano-scaffold (denoted TaNS) for the fabrication of the Si anode. Si films of various thicknesses were subsequently sputtered onto TaNs at an acute angle in order to exploit the shadowing effect by TaNs; this led to Si initially growing in a columnar structure (FIG. 1A, step 2). Column diameters increased with thickness until the column tops contacted one another, closing the surface via the formation of a vaulted (arched) structure (FIG. 1B). Further Si deposition formed a continuous amorphous film via Volmer-Weber (island) growth, labelled as the sedimentary structure (FIG. 1C). Subsequent thermal annealing (FIG. 1A, step 3) enhanced defect mobility and eventual annihilation at the surfaces of each structure. In the case of columnar structures, this process increased their rigidity. Conversely, in sedimentary structures voids remained trapped inside the Si layers, as their migration barrier towards some free surface was significantly higher, resulting in sponge-like porous films.

Variations in Si film structures affect profoundly their mechanical properties. In PeakForce quantitative nanomechanical mapping (PF-QNM) measurements performed here, a nanoindenter exerts a vertical force (FIG. 1D-1F, gray arrow) on the top of each structure. In the columnar structure, compressive stresses lead to each column maintaining its shape and individuality (FIG. 1D, white arrows). The columns readily deform until they touch one another and a clamping effect hinders further deformation. This leads to an increase in E with film thickness, due to increased proximity of the columns. The extreme case occurs in the vaulted structure (FIG. 1E), where the tops of the columns are already in touch with each other; as a result, clamping occurs immediately under the force of the nanoindenter without need for initial deformation, and high E value is measured. This effect resembles arch action as described in civil engineering, where an arch transmits stress to the ground and responds by pushing outward. In the sedimentary structure (FIG. 1F), E is related to surface domes; under force from the nanoindenter, Si atoms at hilltops easily diffuse to valleys. E is also affected by underlying pores which soften the Si layer. As a result, low E values are registered.

The vaulted structure can be used as a nanostructure unit capable of dissipating lithiation (or other) stress while avoiding the cracking observed in electrodes based on the sedimentary structure. When the vaulted structure is vertically reiterated (that is, a vaulted nanostructure is deposited on top of another repeatedly, with each layer forming a single vaulted nanostructure unit), a thin film electrode is created which increases the amount of Si active material, while maintaining optimised mechanical and surface stability during battery cycling. Most importantly, the concept of nano-vault architecture as a repeating nanostructure unit can be applied broadly in the design of novel materials requiring high stress tolerance.

### <4. Correlation Between Morphology and Mechanical Properties>

Henceforth, samples are named according to the scheme h^{X}, where h is the film thickness (in nm) and X designates the structure type: C (columnar), V (vaulted), and S (sedimentary).

The nanoporous TaNS consists of crystalline Ta nanoparticles (3 nm in diameter and narrow-size distribution) 12a, 14 which maintain their individuality due to CBD enabling soft landing. 15 Transmission electron microscopy (TEM) lamella images (FIGS. 2A, 2B) show TaNS thickness of ˜10 nm and confirm the amorphous nature of the overlaid Si layer. Si thin film thickness increases linearly with time at a rate of 1.69 nm min-1 (via X-ray reflection (XRR), FIG. 7A-7B, 8A-8F). Although the Ta content is less than 0.5 at. %, as estimated by X-ray photoelectron spectroscopy (XPS, FIG. 9A-9C), it induces granular morphology (FIGS. 2D, 2D), and ensuing high roughness to the Si films (in the range of 3.3-3.8 nm, vs. 0.8 nm when Si is grown directly on the substrate, FIG. 7A-7B).

Sample 54^{V} presents columns of increasing diameter, resembling inverse truncated cones that touch at the top, forming a vaulted structure as shown by cross-sectional scanning electron microscopy (SEM, FIG. 2E). This columnar structure (which begins to form at the start of the Si growth phase, FIG. 10 for 25 C) results from the shadowing effect of TaNS, due to the disruption TaNS brings to the incident beam of Si atoms. The columnar structure is also observed at the bottom of 216^{S} (FIG. 2F); however, as more Si is deposited on the vaulted layer, the Si stratum becomes continuous without long-range structural ordering, due to the amorphous nature of sputtered Si. Subsequently, domes are formed on top of the continuous film, reducing the local surface energy.

These domes withstand compressive stresses initially until a limit is reached, whereupon the stresses become tensile. This causes diffusion of Si adatoms from hilltops to valleys. As domes coalesce, the thickness of the continuous film increases, which is typical for Volmer-Weber (island) thin film growth.

Topography and elastic modulus mapping of samples 25^{C}, 54^{V}, and 155^{S} show cusps and valleys at the nanoscale, measured by PF-QNM using an atomic force microscope (AFM) operated in PeakForce tapping mode (FIG. 3A). Si samples were prepared on Si (111) for these measurements, although E measurements are valid for any substrate when TaNS is deposited between the substrate and sputtered Si (FIG. 11A-11B). All sedimentary samples show very strong correlation (−1) between topographic and E features (FIG. 12A-12D); thus, E cusps and valleys are related to surface morphology. Reduced correlation is found for the vaulted structure (0.8) that decreases notably for the columnar structure (with dispersed values in the range of 0-0.6). This suggests that other factors besides surface morphology are responsible for E cusps and valleys, probably associated with the presence of honeycomb-like density deficit regions in-between columnar structures (void networks), and the existence of incomplete arches in 54^{V}.

E value distribution in mappings is shown in histograms (FIG. 3B), and for each sample thickness is associated with an E value peak (FIG. 3C). Samples with columnar structure show polynomial increase with film thickness, being similar for 15^{C} and 25^{C} (−40 GPa), that is probably related to TaNS. E increases with film thickness until the columns touch each other forming multiple arches, and E reaches maximum with extremely high values reaching up to 250 GPa. Sedimentary structures have similar E values to columnar structures (−40 GPa), independent of film thickness.

Control experiments where step 3 of the fabrication process was omitted confirmed the importance of thermal annealing for the strengthening of the columnar structures (but not the sedimentary structure) through the mobilisation and ensuing eradication of voids (FIG. 13A-13F). The strong correlation with topographic mappings implies that E measurements are restricted to the domed structure of the Si surface. This is different than in columnar and vaulted samples, in which the granular surface represents the column tops.

### <5. Explanation of Structural and Mechanical Characteristics By Atomistic Simulations>

A group of molecular dynamics (MD) simulations were performed that mimic the deposition process of the TaNS-Si film composite onto a rotating substrate holder. In the presence of Ta nanoparticles the vicinity of the nanoparticles was shadowed from the deposited Si atoms, as shown in FIG. 4A, left panel (also FIGS. 14A-14C, 15); hence the columnar structure first formed on top of the Ta nanoparticles. With prolonged deposition time, the columns merged, initially forming the vaulted and finally the sedimentary structure, in excellent agreement with the experiment. In contrast, in control simulations without nanoparticles (FIG. 4B) a sedimentary structure formed from the beginning of the deposition. Thus, it is clearly demonstrated that the shadowing effect of the TaNS is essential for the formation of the vaulted structure.

Surface construction analysis accentuates the location and size of voids inside the deposited structures, as indicated by the grey surface meshes in FIG. 4A, 4B, right panels. Within the same simulation, large voids form only inside the sedimentary region, and the estimated porosity increases from 0.09 to 0.3. This can be explained by the finite-size effect of the columnar structure. Small vacancy clusters near open surfaces can be filled up quickly by a few displacements of surface atoms or by newly deposited atoms. In contrast, larger voids forming under the surface of the sedimentary structure need a collective movement of Si atoms, which is significantly slower. Moreover, the activation enthalpy (migration barrier) for the self-diffusion in amorphous Si is about 2.7 eV; therefore, once large voids are formed in the sedimentary region, they remain stable under the annealing condition.

Mechanical characteristics derived from PF-QNM measurements were explained by simulated compress-hold-decompress loops. As shown in FIG. 4C, we selected eight instances with nanoparticles from the first group of simulations. The evolution of the feedback forces can be tracked with time and the displacement of the plates on top of the Si layers. The feedback forces clearly distinguish the different stages, as indicated by the dashed lines in FIG. 4D. From the force vs. displacement curves we extracted the stiffness of the structures during the loading phase, indicated by the solid lines in FIG. 4E. Clearly, the stiffness reached a maximum when

the columnar structure evolved into the vaulted structure, as shown in FIG. 4F, which resembles remarkably the experimental PF-QNM measurements of FIG. 3C. This can be explained by the fact that in the initial elastic deformation zone (displacement from 1 nm to 2 nm) the vaulted structures (i.e., 20.8-26.3 nm cases) reach the maximum contact area—minimum porosity combined with relatively small thickness. The stiffness extracted from the decompression phase (where the contact area is approximately the same for all structures) follows spring-like behaviour with porosity of 0.3 (FIG. 16A-16B).

### <6. Vaulted Structure as a Building Block in Electrodes for LIBs>

The commonly reported fracture of Si anodes is associated with the extensive volumetric expansion (300-400%) accumulating mechanical stress in the electrode. This effect limits the thickness and size of Si thin films and nanoparticles, respectively, utilised as anodes in LIBs. Sputtered Si thin films on rough substrates may increase the stability of the electrode during cycling, but film thickness remains limited.

The improvement in mechanical strength achieved through arch action can help overcome this limitation. Charge cycles of samples 15^{C}, 54^{V}, and 155^{S} at 0.5 C in semibatteries with Li foil as reference and counter electrodes (FIG. 5A) represent each sample type (FIG. 17A-17B) and indicate the decisive role of nanostructure. 54^{V} shows the highest capacities during the first 60 cycles, followed by 15^{C}. Both samples show an initial increase in capacity associated with the activation phenomenon (FIG. 18A-18I). Despite the 250% expansion of 54^{V} (FIG. 19), the capacity retention is similar to that of the columnar structure, but with higher Coulombic efficiency. In contrast, 155^{S} shows fast capacity fade, especially during the first fifteen cycles, attributed to loss of active material due to detachment from the substrate, as attested by SEM (FIG. 18A-18I). This effect can also explain the high Coulombic efficiency of 96-100% for 155^{S} (FIG. 5B), compared with 85-96% registered for sample 54^{V}, and 60-85% for 15^{C}. For samples 54^{V} and 15^{C} the Coulombic efficiency reflects an irreversible consumption of lithium in side reactions during charge (usually the formation of SEI), and low values during cycling indicate the exposure of fresh electrode to the electrolyte due to fracturing. Thus, the vaulted structure of 54^{V} forms a seal between the electrode and the electrolyte, reducing lithium consumption in side reactions.

Electrochemical impedance spectroscopy (EIS, FIG. 20A-20D) confirms that the resistance associated with electrode/electrolyte interface phenomena (SEI and charge transfer) is three times higher for 15^{C} than for 54^{V}. Indeed, the sealed surface of 54^{V} protects the surface while allowing the same fast charge/discharge as in the columnar structure (charge-discharge and Coulombic efficiency plots at 5 C are shown in FIG. 21A-21B). This is in agreement with a recent chemomechanical model demonstrating that anode materials of high E values can sustain higher lithiation stresses before buckling.

Since the vaulted structure is generated by the TaNS, it can be assembled independently of the substrate. This is demonstrated when a second TaNS is deposited on top of an existing Si vaulted structure, followed by further Si deposition. The second TaNS layer prevents columns from merging toward a sedimentary structure, generating a second vaulted structure instead (FIG. 21A-21B), denoted D54^{V} in reference to the double 54^{V} layer. The D54^{V} sample also demonstrates a heterogeneous E profile, with values in the same range observed for the single layer (FIG. 23A-23B).

To rule out film thickness effects, the electrochemical performance of sample D54^{V} was compared with a sedimentary sample, 110^{S} (i.e., with a single TaNS layer) that contains the same amount of Si (FIG. 5C-5D). The initial capacity of D54^{V} is 3230 mAh g-1, and after ˜5% increase for the activation phenomenon in the first cycles, it shows capacity retention of 88% after 100 cycles (2832 mAh g-1). In contrast, a strong activation phenomenon is observed for the 110^{S} sample, reaching a maximum capacity of 2700 mAh g-1 after 20 cycles and decreasing 45% after 100 cycles (1477 mAh g-1). D54^{V} also shows improved electrochemical performance compared to single-layer 54V, with similar capacity during the first 50 cycles but higher capacity retention and Coulombic efficiency, with values ranging between 90 and 98% (FIG. 24A-24B). The construction of the bilayer strongly enhances the mechanical stability of the electrode, which retains this structure after charge-discharge cycling (FIG. 25).

The electrochemical response of the studied electrodes is strongly coupled with their mechanical and structural properties. The single-layer vaulted structure shows the highest E values, due to arch action that is capable of transferring compressive stresses to the columns. It can dissipate stress caused by the lithiation process, preventing film cracking that impairs sedimentary structures. It can also seal the electrode significantly reducing side reactions and the formation of SEI that columnar structures suffer from. After 20 cycles, there is a capacity fade and the Coulombic efficiency maximum is 95%. This may be attributed to free space for expansion in the perpendicular direction that can cause mechanical failure in the long term, despite the clamping effect in the lateral directions of the film. However, repeating the vaulted structure imposes a new clamping effect in the perpendicular direction, improving both capacity retention and Coulombic efficiency, thus improving overall mechanical stability.

### <7. Conclusions>

A vaulted structure with the resultant arch action is introduced for the first time at the nanoscale. This structure demonstrates possibilities for new designs in Si anodes for LIBs, but is also eligible for other materials and applications where surface mechanics play a critical role. Arch action is observed during columnar growth, when columns contact each other sealing the anode in a vault-like structure; it favours dissipation of stress, preventing Si electrodes from cracking during cycling and effectively reducing capacity fade. SEI formation is significantly reduced compared with columnar arrangements, minimising lithium consumption and improving Coulombic efficiency, while maintaining the advantages of columnar structures such as high charge/discharge rates of the battery. When this nanostructural unit is repeated along the perpendicular axis, a material is created with a stable surface that can effectively release imposed stresses. This is observed with the construction of a double-layer aqueduct-like vaulted structure which improves sealing, observed through higher Coulombic efficiency and mechanical stability, indicating arch action reinforcement. Most importantly, the design of this novel nanoarchitecture offers plenty of room for further optimisation, e.g., by using different deposition techniques for production upscale, or by changing the nanoparticle scaffold materials, etc.

A nanoarchitecture unit, called nano-vault, is grown by a scalable physical methodology;

The nano-vault architecture is formed in a columnar film (composed of columns that touch each other at the top, forming arches) with optimized characteristics;

The presence of extensive nano-voids and sealed surface result in a material with high mechanical stability for films under strong and variable stress action;

The nano-vault structural unit is grown using nanoparticles as scaffold, enabling vertical repetition of the composite in a multilayer that reinforces the optimized characteristics observed in the monolayer.

The nano-vault architecture is tested in Si films for Li-Ion Battery anodes, showing high Coulombic efficiency, fast charge-discharge response and improved cycleability.

### <8. Experimental Section>

### <8-1. Sample Preparation>

All samples were prepared using a gas-phase deposition system (Mantis Deposition Ltd) at high vacuum (2.0×10⁻⁸ mbar), supported by a rotatory holder (2 rpm for all depositions) to yield homogeneous film deposition. For Ta nanoparticle deposition, Ar gas flow of 60 standard cubic centimetres per minute, DC magnetron power of 45 W, and aggregation zone length of 100 mm were selected. The Si thin film was deposited with a 110 W RF-sputtering source, using an Ar pressure of 2.1×10⁻³ mbar. The magnetron sputtering targets, Silicon (n-type, purity >99.999% purity, resistivity <0.001 W m) and Tantalum (>99.95% purity), were purchased from Kurt J. Lesker. All depositions were performed at ambient temperature (˜298 K, as measured by the substrate holder thermocouple), and with no external bias applied to the substrate. Finally, all anodes were annealed at 150° C. for 60 minutes at Ar pressure of 8×10⁻³ mbar.

### <8-2. FIB-SEM and TEM Lamellae Characterisation>

Cross-sections and sample surfaces were imaged by means of focused ion beam (FIB) milling combined with SEM using a FEI Helios G3 UC FIB-SEM. The same FIB-SEM system, equipped with a Pt deposition needle and an OMNIPROBE™ extraction needle, was used to prepare TEM lamellae. They were prepared using the conventional “H-bar” technique by cutting two trenches from the sample where a strip of Pt thin film was deposited in-situ to protect the surface area of interest while milling. The thin slab milled from the sample was then thinned to about 40 nm so that the TEM beam could pass through. Using the extraction needle, lamellae were then transported to the tops of TEM half grids where they welded with the Pt deposition needle. TEM lamellae were imaged using FEI Titan Environmental TEM equipped with a spherical aberration image corrector at an operating voltage of 300 kV.

### <8-3. PF-QNM Measurements>

Surface morphology and elastic moduli of Si samples were measured using an AFM (Multimode 8, Bruker) operating in Peak Force tapping mode. Sample imaging and PF-QNM™ measurements were performed with an ultra-high force cantilever (DNISP-HS) with a diamond tip from Bruker (˜71.5 kHz resonant frequency, 432 N/m spring constant and ˜40 nm of nominal tip radius). The standard relative method was used for E measurements with fused silica (nominal E: ˜72 GPa) as a reference sample. By this method, the cantilever deflection sensitivity calibration was first performed on a hard-sapphire sample by fitting the linear portion of the force-distance curve in ramp mode. The spring constant value during measurements was taken as 432 N/m from the calibration sheet provided by the manufacturer. The reference sample (fused silica) was then loaded for PF-QNM measurement followed by peak force set point adjustment in order to get the desired deformation (1-2 nm). Subsequently, the tip radius parameter was changed so that the measured elastic modulus of the reference sample met its exact value (72 GPa). After calibration with the reference sample for the tip radius, PF-QNM measurement was performed on TaSi samples and the peak force set-point was adjusted so that its deformation matched with the reference sample. AFM images (512×512 pixel) were captured at scan rate of 0.5 Hz and analysed with Nanoscope Analysis (Ver. 9) software. While no reduction process was applied to the modulus mapping images or data, it was a quantitative property measurement by the standard relative method. Tip cleaning was performed with indentations on a gold surface followed by separate tip calibration for each sample.

For PF-QNM, a z-piezo sensor tapped on the surface of the sample and measured the force-distance curve at every imaging pixel. From the force-distance curve, E was determined by fitting the DMT model to the section of the force-distance curve where the sample and the tip were in contact, using the following equation:

Fₜᵢₚ=4/3Eᵣ\sqrt{Rd³}+F_{adh}=K(x) [Math. 4]

where Fₜᵢₚ, R, d, F_{adh}, and k are the applied force, tip radius, deformation, adhesion force, and the cantilever spring constant, respectively.

The reduced modulus (Eᵣ) is related to Young's modulus (E) of the sample as:

$$\frac{1}{{E}_{r}} = \frac{1 - {v}^{2}}{E} + \frac{1 - {v}_{i}^{2}}{{E}_{i}} \qquad [ Math . 5 ]$$

where Eᵢ and vᵢ are Young's modulus and Poisson's ratio of the AFM tip and v is the Poisson's ratio of the sample. The contribution of the second term in Eq. 2 is negligible, since Eᵢ>>E.

### <8-4. Electrochemical Characterisation>

For electrochemical characterisation, samples were prepared on Cu foil (0.25 mm thick, Puratronic 99.9985%, AlfaAesar). Electrochemical characterisation was carried out using a two-electrode Swagelok cell with metallic lithium foil as a reference and counter electrode. Ethylene carbonate (EC, >99%), diethyl carbonate (DEC, >99%), and lithium hexafluorophosphate (LiPF₆, >99.99%) for the electrolyte were purchased from Sigma-Aldrich, as well as the lithium foil (thickness 0.38 mm, 99.9%) and Celgard (25 mm thickness) from MTI Corporation was used as a separator. The electrolyte solution was 1.0 M LiPF₆ in 50:50 (w/w) mixture of EC:DEC. All batteries were assembled inside an Ar glovebox (UNICO) with O₂ and humidity below 0.25 ppm. Charge-discharge measurements were performed using two 8-channel battery analysers (0.005-1 mA and 0.02-10 mA up to 5V, MTI Corp.) in the voltage window of 0.01-1 V. For the calculation of charge-discharge rate, 1 C was defined as 3579 mAh g⁻¹. After three cycles at 0.5 C, the semibattery was opened inside the Ar glovebox and the anode rinsed three times with dimethyl carbonate (DMC, >99%) and dried under high vacuum (1.0×10⁻⁶ mbar) for at least 12 hours. The samples were taken outside and scratched with a diamond pen before introduction into the FIB-SEM.

### <8-5. Computational Methods>

We performed two groups of MD simulations (i) to elucidate the formation mechanism of the vaulted structure, and (ii) to explain the variation in mechanical properties of the structures at different growth stages.

In the first group, we simulated the deposition of the silicon layer with and without the nanoparticle scaffold. Initially, an amorphous Si substrate was prepared by a fast heating (3000 K for 100 ps)-quenching (500 K for 100 ps) process in the isothermal-isobaric ensemble at 0 Bar. The size of the thermalised simulation cells was 109×109×55 angstrom initially. Next, we opened the top surface and fixed an atomic layer within 6 angstrom at the bottom, and performed additional relaxation for 50 ps in the canonical ensemble. For the structure with the nanoparticle scaffold, the nanoparticle was deposited on the amorphous silicon substrate naturally. We placed a diamond-lattice silicon nanoparticle 5 nm in diameter at 15 angstrom above the surface at the (0, 0) position laterally.

The silicon nanoparticle was thermalised at 500 K for 50 ps and was next given an additional velocity of 20 m/s so it would land on the substrate, where it was allowed to relax for another 50 ps. Film growth was simulated by adding a new Si atom from the top of the cell every 200 MD steps; 215563 Si atoms were added in total (at an average deposition rate of 1.1 nm/ns). In order to mimic the rotating substrate of the experimental setup, the initial velocities of the deposited atoms were set to rotate at a rate of 1 round/ns, performed in 20-ps steps. The angle of incidence was 30° from the surface and the total velocity was 1000 m/s. No scaling of velocity was applied to the non-deposited atoms. The temperature of the deposited atoms (except those fixed at the bottom) was controlled by applying a Langevin thermostat to the group of deposited atoms located 1 nm below the open surface. This group was updated every 2.8 ns, so the atoms deposited during that period were scaled after the update. The simulation was carried out for about 40 ns with a time step of 1 fs. We also performed benchmarking simulations with different nanoparticle and cell sizes and temperatures, or with two nanoparticles explicitly following the same procedures as described above.

The second group of simulations involved mechanical measurements with a simulated AFM tip; deposited structures of different thicknesses (after 5, 10, . . . , 40 ns of deposition time) were picked out and relaxed at 500 K for 200 ps. Later, we placed a flat diamond carbon plate 5 angstrom in thickness at 5 angstrom above the surface. Each AFM measurement was simulated until the loading depth reached about 3.5 nm (0.01 nm/ps for 400 ps), followed by a holding step at a fixed position of the tip for 600 ps. Finally, the tip was retracted at a speed of 0.002 nm/ps for 400 ps. The evolution of the feedback force was recorded.

All simulations were conducted using the classical MD code LAMMPS, and the visualisation of the results was done with OVITO. We used an environment-dependent interatomic potential (EDIP) parametrised for silicon. The EDIP significantly outperforms other existing potentials for silicon, including the popular Stillinger-Weber and Tersoff potentials, when tested for bulk phases, defects, and phase transitions. EDIP has been used to study the liquid-amorphous transition, self-diffusion, crystal plasticity, brittle fracture, solid phase epitaxial growth, and amorphous structures. For the C-Si interactions in the purely repulsive Ziegler-Biersack-Littmark (ZBL) potential was used to obtain a non-adhesive feedback-force curve.

1. A composite nanoarchitecture unit, comprising:
a columnar film grown on top of another layer where the columns touch each other at the top forming arches having optimized characteristics.

2. The composite nanoarchitecture unit according to claim 1,
wherein the columnar film is an amorphous Si film in an annealed state.

3. The composite nanoarchitecture unit according to claim 1,
wherein the columnar film is grown on top of a layer of metallic nanoparticles.

4. The composite nanoarchitecture unit according to claim 1,
wherein the optimized characteristics include at least one of a low lithium consumption during formation of solid electrolyte interface in Li-Ion Batteries, high Coulombic efficiency, and high mechanical stability pertinent to any application where the surface of the film is under strong and variable stress action.

5. A multilayer composite including at least two vertical repetitions of the composite nanoarchitecture unit of claim 1.

6. The multilayer composite according to claim 5,
wherein the optimized characteristics compared with those of the monolayered structure include both a high Coulombic efficiency of a lithium ion battery and the mechanical stability of the film, indicating arch action reinforcement.

7. A manufacturing method for a composite nanoarchitecture unit, the method comprising the steps of:
a) depositing nanoparticles on substrates from the gas phase; and
b) growing a columnar film on a layer of nanoparticles,
wherein column diameters in the columnar film increased with thickness until the column tops contacted one another, closing the surface via the formation of an arched structure in the step b).

8. The manufacturing method according to claim 7,
wherein growth of the columnar film is stopped as soon as possible after arch formation in the step b).

9. The manufacturing method according to claim 7, further comprising the step of
c) thermal annealing of the columnar film.

10. The manufacturing method according to claim 7,
wherein the columnar film is an amorphous Si film.

11. The manufacturing method according to claim 7,
wherein the nanoparticles are metallic nanoparticles.
